(19) United States
(12) Patent Application Publication
(10) Pub. No.: US 2020/0251490 A1
(43) Pub. Date: Aug. 6, 2020

(54) SEMICONDUCTOR MEMORY DEVICE

(71) Applicant: Toshiba Memory Corporation, Minato-ku (JP)

(72) Inventors: Sota MATSUMOTO, Yokkaichi (JP); Junichi SHIBATA, Yokkaichi (JP); Takahito NISHIMURA, Kuwana (JP); Kazuhiro WASHIDA, Yokkaichi (JP)

(73) Assignee: Toshiba Memory Corporation, Minato-ku (JP)

(21) Appl. No.: 16/522,730

(22) Filed: Jul. 26, 2019

(30) Foreign Application Priority Data
Feb. 5, 2019 (JP) 2019-019065

(51) Int. Cl. H01L 27/11582; H01L 27/11524; H01L 27/11556; H01L 27/1157; H01L 23/528; H01L 23/522; H01L 21/768

(52) U.S. Cl. CPC H01L 27/11582; H01L 27/11524; H01L 27/11556; H01L 21/76877; H01L 23/5283; H01L 23/5226; H01L 21/76816; H01L 27/1157

(57) ABSTRACT

A semiconductor memory device according to an embodiment includes, a stacked portion and a pillar. The stacked portion is provided in a first region including a memory cell and in a second region. The stacked portion includes first and second conductive layers and a first insulating layer. The first conductive layers are stacked in a first direction. The second conductive layers are stacked in the first direction above the first conductive layers. The first insulating layer is provided between an uppermost first conductive layer and a lowermost second conductive layer. The pillar penetrates the first and second conductive layers and the first insulating layer. A thickness of the first insulating layer is greater in the

### CROSS-REFERENCE TO RELATED APPLICATIONS

This application is based upon and claims the benefit of priority from Japanese Patent Application No. 2019-019065, filed Feb. 5, 2019, the entire contents of which are incorporated herein by reference.

### FIELD

Embodiments described herein relate generally to a semiconductor memory device.

### BACKGROUND

A NAND-type flash memory capable of storing data in a nonvolatile manner is known.

### BRIEF DESCRIPTION OF THE DRAWINGS

FIG. 1 is a block diagram showing a configuration example of a semiconductor memory device according to a first embodiment.

FIG. 2 is a circuit diagram showing an example of a circuit configuration of a memory cell array provided in the semiconductor memory device according to the first embodiment.

FIG. 3 is a plan view showing an example of a planar layout of a memory cell array provided in the semiconductor memory device according to the first embodiment.

FIG. 4 is a plan view showing an example of a detailed planar layout of a memory cell array in a cell area of the semiconductor memory device according to the first embodiment.

FIG. 5 is a cross-sectional view taken along line V-V of FIG. 4 and showing an example of a cross-sectional structure of the memory cell array in the cell area of the semiconductor memory device according to the first embodiment.

FIG. 6 is a plan view showing an example of a detailed planar layout of the memory cell array in a hookup area of the semiconductor memory device according to the first embodiment.

FIG. 7 is a cross-sectional view showing an example of the cross-sectional structure of the memory cell array in the hookup area of the semiconductor memory device according to the first embodiment.

FIG. 8 is a flowchart illustrating an example of a method of manufacturing the semiconductor memory device according to the first embodiment.

FIG. 9 is a cross-sectional view of a memory cell array illustrating an example of a manufacturing process of the semiconductor memory device according to the first embodiment.

FIGS. 10 and 11 are cross-sectional views of the memory cell array illustrating an example of a manufacturing process of the semiconductor memory device according to the first embodiment.

FIG. 12 is a plan view of a memory cell array illustrating an example of a manufacturing process of the semiconductor memory device according to the first embodiment.

FIGS. 13 and 14 are cross-sectional views of the memory cell array illustrating an example of a manufacturing process of the semiconductor memory device according to the first embodiment.

FIGS. 15 and 16 are plan views of the memory cell array illustrating an example of a manufacturing process of the semiconductor memory device according to the first embodiment.

FIGS. 17, 18, 19 and 20 are cross-sectional views of the memory cell array illustrating an example of a manufacturing process of the semiconductor memory device according to the first embodiment.

FIG. 21 is a plan view of a memory cell array illustrating an example of a manufacturing process of the semiconductor memory device according to the first embodiment.

FIG. 22 is a cross-sectional view of a memory cell array illustrating an example of a manufacturing process of the semiconductor memory device according to the first embodiment.

FIG. 23 is a cross-sectional view showing an example of a cross-sectional structure of a memory cell array according to a comparative example of the first embodiment.

FIG. 24 is a plan view showing an example of a detailed planar layout of the memory cell array in the hookup area of a semiconductor memory device according to a second embodiment;

FIG. 25 is a cross-sectional view showing an example of the cross-sectional structure of the memory cell array in the hookup area of the semiconductor memory device according to the second embodiment.

FIG. 26 is a flowchart illustrating an example of a method of manufacturing the semiconductor memory device according to the second embodiment.

FIG. 27 is a cross-sectional view of a memory cell array illustrating an example of a manufacturing process of the semiconductor memory device according to the second embodiment.

FIG. 28 is a plan view of a memory cell array illustrating an example of a manufacturing process of the semiconductor memory device according to the second embodiment.

FIGS. 29, 30, 31, 32 and 33 are cross-sectional views of the memory cell array illustrating an example of a manufacturing process of the semiconductor memory device according to the second embodiment.

FIG. 34 is a plan view of a memory cell array illustrating an example of a manufacturing process of the semiconductor memory device according to the second embodiment.

FIGS. 35 and 36 are cross-sectional views of the memory cell array illustrating an example of a manufacturing process of the semiconductor memory device according to the second embodiment.

FIG. 37 is a plan view showing an example of a detailed planar layout of the memory cell array in the hookup area of a semiconductor memory device according to a third embodiment.

FIG. 38 is a cross-sectional view showing an example of the cross-sectional structure of the memory cell array in the hookup area of the semiconductor memory device according to the third embodiment.

FIG. 39 is a flowchart illustrating an example of a method of manufacturing the semiconductor memory device according to the third embodiment.

FIG. 40 is a cross-sectional view of a memory cell array illustrating an example of a manufacturing process of the semiconductor memory device according to the third embodiment.

FIG. 41 is a table illustrating an example of a method of processing a contact hole in the semiconductor memory device according to the third embodiment.

FIG. 42 is a cross-sectional view of a memory cell array illustrating an example of a manufacturing process of the semiconductor memory device according to the third embodiment.

FIG. 43 is a plan view showing an example of a detailed planar layout of the memory cell array in the hookup area of a semiconductor memory device according to a fourth embodiment.

FIG. 44 is a cross-sectional view showing an example of the cross-sectional structure of the memory cell array in the hookup area of the semiconductor memory device according to the fourth embodiment.

FIGS. 45 and 46 are plan views of the memory cell array illustrating an example of a manufacturing process of the semiconductor memory device according to the fourth embodiment.

FIG. 47 is a cross-sectional view of the memory cell array illustrating an example of a manufacturing process of the semiconductor memory device according to the fourth embodiment.

FIG. 48 is a plan view showing an example of a detailed planar layout of a memory cell array in the hookup area of a semiconductor memory device according to a modification of the fourth embodiment.

FIG. 49 is a cross-sectional view showing an example of the cross-sectional structure of the memory cell array in the hookup area of the semiconductor memory device according to the modification of the fourth embodiment.

### DETAILED DESCRIPTION

In general, according to one embodiment, a semiconductor memory device includes, a stacked portion, a pillar, a plurality of first contacts, and a plurality of second contacts. The stacked portion is provided in a first region including a memory cell and in a second region different from the first region. The stacked portion includes a plurality of first conductive layers, a plurality of second conductive layers and a first insulating layer. The first conductive layers are stacked in a first direction above a substrate. The first conductive layers are separated from each other. The second conductive layers are stacked in the first direction above the first conductive layers. The second conductive layers are separated from each other. The first insulating layer is provided between an uppermost one of the first conductive layers and a lowermost one of the second conductive layers. The pillar penetrates the first conductive layers, the second conductive layers and the first insulating layer in the first region. The first contacts are respectively connected to the first conductive layers in the second region. The second contacts are respectively connected to the second conductive layers in the second region. A thickness of the first insulating layer is greater in the first region than in the second region in the first direction.

Hereinafter, embodiments will be described with reference to the accompanying drawings. Each embodiment illustrates an apparatus and a method for embodying the technical idea of the invention. The drawings are schematic or conceptual, and the dimensions and scales of the drawings are not necessarily the same as those of actual products. The technical concept underlying the present invention is not limited by the shapes, structures, arrangements, etc. of the constituent elements.

In the description below, elements having the same functions and configurations will be denoted by the same reference symbols. The numbers after the letters of reference symbols are referred to by the reference symbols containing the same letters and are used to distinguish between elements having similar configurations. Where elements denoted by reference symbols including the same symbols need not be discriminated from each other, they will be denoted by reference symbols including only letters.

### [1] First Embodiment

A semiconductor memory device 1 according to the first embodiment will be described.

### [1-1] Configuration of Semiconductor Memory Device 1

### [1-1-1] Overall Configuration of Semiconductor Memory Device 1

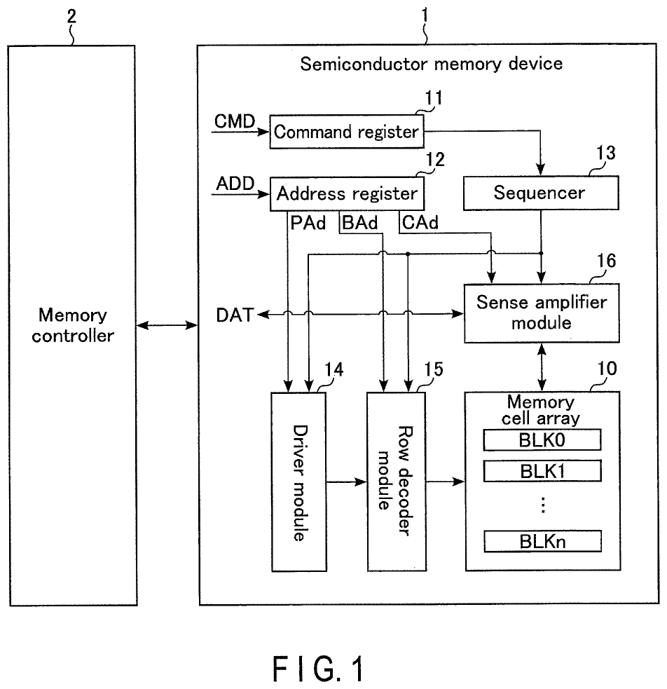

FIG. 1 is a block diagram showing a configuration example of the semiconductor memory device 1 according to the first embodiment. The semiconductor memory device 1 is a NAND flash memory capable of storing data in a non-volatile manner and is controlled by an external memory controller 2. Communications between the semiconductor memory device 1 and the memory controller 2 support, for example, a NAND interface standard.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The block BLK is an aggregation of memory cells capable of storing data in a nonvolatile manner, and is used, for example, as a data erase unit. The memory cell array 10 is provided with a plurality of bit lines and a plurality of word lines. For example, each memory cell is associated with one bit line and one word line. A detailed configuration of the memory cell array 10 will be described later.

The command register 11 holds a command CMD which the semiconductor memory device 1 receives from the memory controller 2. The command CMD includes, for example, instructions to cause the sequencer 13 to execute a read operation, a write operation, an erase operation, etc.

The address register 12 holds address information ADD which the semiconductor memory device 1 receives from the memory controller 2. The address information ADD includes, for example, a block address BAd, a page address PAd, and a column address CAd. For example, the block address BAd, the page address PAd, and the column address CAd are used to select a block BLK, a word line and a bit line, respectively.

The sequencer 13 controls the overall operation of the semiconductor memory device 1. For example, the sequencer 13 controls the driver module 14, row decoder module 15, sense amplifier module 16, etc., based on the command CMD held in the command register 11, to execute a read operation, a write operation, an erase operation, etc.

The driver module 14 generates voltages used in the read operation, write operation, erase operation, etc. Also, the driver module 14 applies the generated voltages to the signal line corresponding to the selected word line, based on, for example, the page address PAd held in the address register 12.

The row decoder module 15 selects one of blocks BLK in the corresponding memory cell array 10, based on the block address BAd held in the address register 12. Also, the row decoder module 15 transfers, for example, the voltage applied to the signal line corresponding to the selected word line to the selected word line in the selected block BLK.

The sense amplifier module 16 applies a desired voltage to each bit line in accordance with the write data DAT which is received from the memory controller 2 in the write operation. Further, in the read operation, the sense amplifier module 16 determines the data stored in the memory cell, based on the voltage of the bit line, and transfers the determination result to the memory controller 2 as read data DAT.

The semiconductor memory device 1 and memory controller 2 described above may constitute one semiconductor device by combining them together. Examples of such a semiconductor device include a memory card such as an SD™ card, and a solid state drive (SSD).

### [1-1-2] Configuration of Memory Cell Array 10

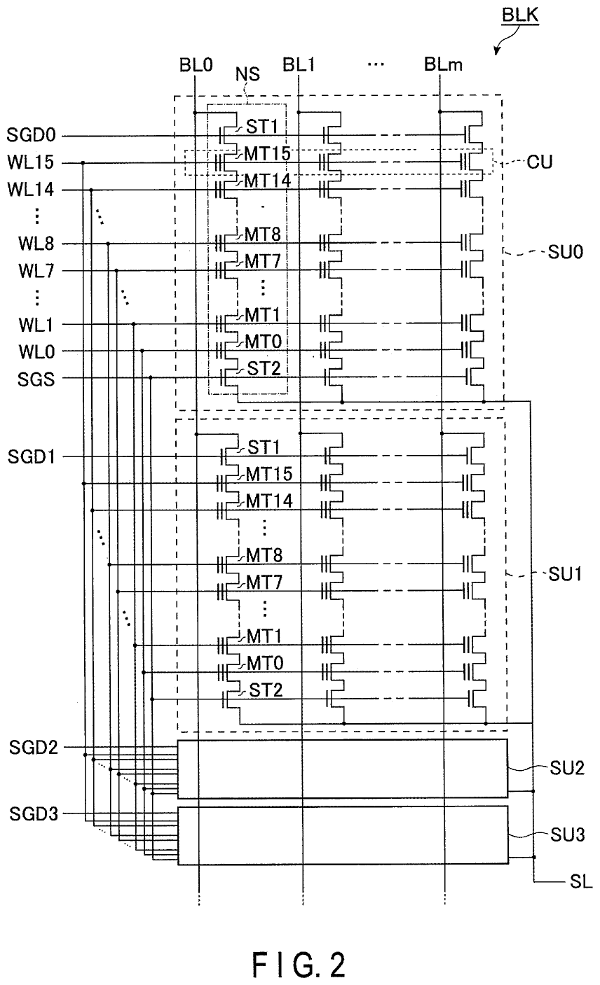

FIG. 2 shows an example of the circuit configuration of the memory cell array 10 provided in the semiconductor memory device 1 according to the first embodiment by illustrating one block BLK extracted out of the blocks BLK included in the memory cell array 10. As shown in FIG. 2, the block BLK includes, for example, four string units SU0 to SU3.

Each string unit SU includes a plurality of NAND strings NS respectively associated with bit lines BL0 to BLm (m is an integer of 1 or more). Each NAND string NS includes, for example, memory cell transistors MT0 to MT15, and select transistors ST1 and ST2. Each of the memory cell transistors MT includes a control gate and a charge storage layer, and holds data in a nonvolatile manner. Select transistors ST1 and ST2 are used for selecting string unit SU during various operations.

In each NAND string NS, memory cell transistors MT0 to MT15 are connected in series. The drain of select transistor ST1 is connected to an associated bit line BL, and the source of select transistor ST1 is connected to one end of serially connected memory cell transistors MT0 to MT15. The drain of select transistor ST2 is connected to the other end of the serially connected memory cell transistors MT0 to MT15, and the source of select transistor ST2 is connected to source line SL.

In the same block BLK, control gates of memory cell transistors MT0 to MT15 are commonly connected to word lines WL0 to WL15, respectively. The gates of select transistors ST1 in string units SU0 to SU3 are commonly connected to select gate lines SGDO to SGD3, respectively. The gates of select transistors ST2 are commonly connected to select gate line SGS.

In the circuit configuration of the memory cell array 10 described above, word lines WL0 to WL7 correspond to memory holes LMH described later, and word lines WL8 to WL15 correspond to memory holes UMH described later. Bit line BL is shared by NAND strings NS to which the same column address is assigned in each string unit SU. Source line SL is shared, for example, by a plurality of blocks BLK.

A set of memory cell transistors MT connected to a common word line WL in one string unit SU are referred to, for example, as a cell unit CU. For example, the storage capacity of the cell unit CU including memory cell transistors MT each storing 1-bit data is defined as “1 page data”. The cell unit CU may have a storage capacity of two page data or more in accordance with the number of bits of data stored in the memory cell transistor MT.

The circuit configuration of the memory cell array 10 provided in the semiconductor memory device 1 of the first embodiment is not limited to the configuration described above. For example, the numbers of memory cell transistors MT and select transistors ST1 and ST2 included in each NAND string NS may be designed to be freely selected numbers. The number of string units SU included in each block BLK may be designed to be a freely selected number.

In addition, one or more dummy word lines may be provided between word lines WL7 and WL8. Where dummy word lines are provided, dummy transistors are provided between memory cell transistors MT7 and MT8 of each NAND string NS in accordance with the number of dummy word lines. The dummy transistors are transistors which have a configuration similar to that of memory cell transistor MT and which are not used for storing data.

### [1-1-3] Configuration of Memory Cell Array 10

An example of the configuration of the memory cell array 10 of the first embodiment will be described below.

In the drawings referred to below, the X direction corresponds to the extending direction of word lines WL, the Y direction corresponds to the extending direction of bit lines BL, and the Z direction corresponds to the direction vertical to the surface of the semiconductor substrate 20 on which the semiconductor memory device 1 is formed. In the plan views, hatching is added where appropriate to make the views easy to see. The hatching added to the plan views is not necessarily related to the materials or characteristics of the hatched elements. In the cross-sectional views, illustration of such elements as an insulating layer (interlayer insulating film), a wiring and a contact is omitted where appropriate to make the views easy to see.

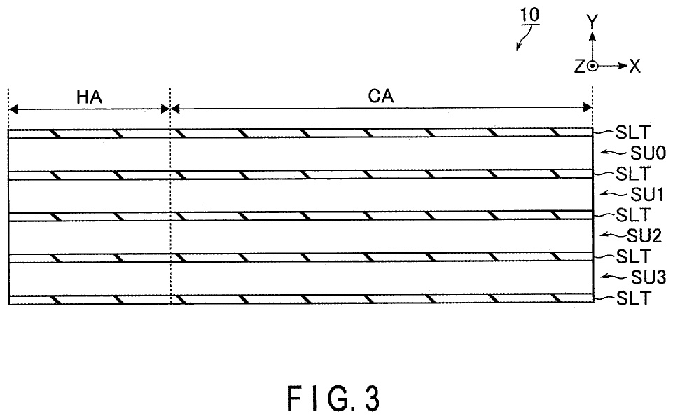

FIG. 3 shows an example of a planar layout of the memory cell array 10 provided in the semiconductor memory device 1 according to the first embodiment, and depicts an area including a configuration corresponding to one block BLK (that is, string units SU0 to SU3). As shown in FIG. 3, the memory cell array 10 includes a plurality of slits SLT.

The slits SLT extend in the X direction and are arranged in the Y direction. The slits SLT include insulators and separate the interconnect layer corresponding to word line WL, the interconnect layer corresponding to select gate line SGD and the interconnect layer corresponding to select gate line SGS respectively. In the present embodiment, the area partitioned by the slits SLT corresponds to one string unit. SU. That is, string units SU0 to SU3 each extending in the X direction are arranged in the Y direction. In the memory cell array 10, for example, the layout shown in FIG. 3 is repeatedly arranged in the Y direction.

The planar layout of the memory cell array 10 described above is divided into a cell area CA and a hookup area HA in the X direction. The cell area CA is an area formed with the NAND string NS. The hookup area HA is an area formed with contacts. The contacts are for electrically connecting the word lines WL and select gate lines SGS and SGD, which are connected to the NAND string NS, to the row decoder module 15. The detailed configuration of the cell area CA of the memory cell array 10 and the detailed configuration of the hookup area HA thereof will be described below.

(Configuration of Cell Area CA of Memory Cell Array 10)

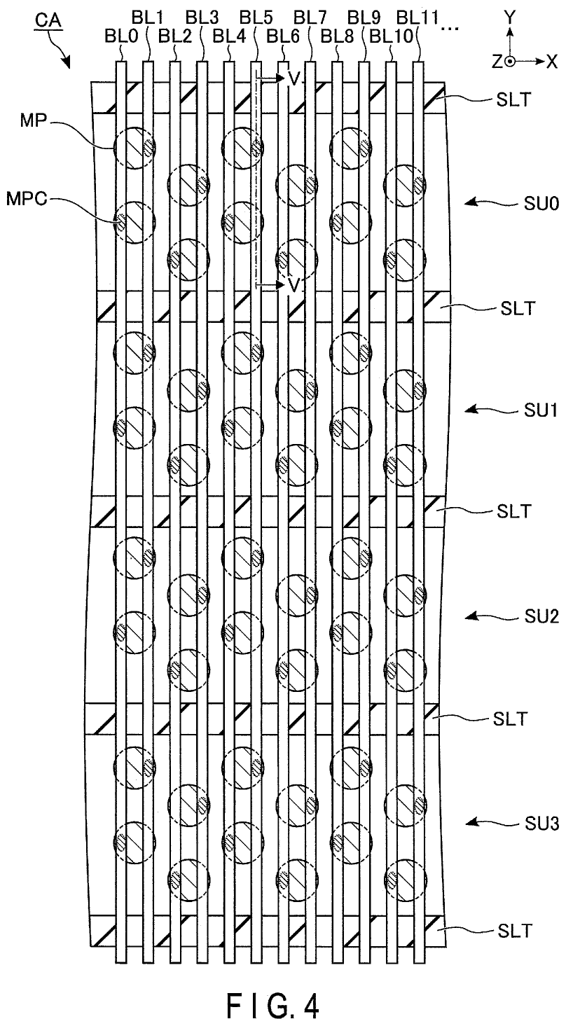

FIG. 4 shows an example of a detailed planar layout in the cell area CA of the memory cell array 10 provided in the semiconductor memory device 1 according to the first embodiment. As shown in FIG. 4, in the cell area CA, the memory cell array 10 includes a plurality of memory pillars MP and a plurality of bit lines BL.

In each of the regions between the adjacent slits SLT, the memory pillars MP are arranged, for example, in four rows and in a staggered manner. The number and arrangement of the memory pillars MP between the adjacent slits SLT are not limited to those mentioned above, and may be modified as appropriate. Each of the memory pillars MP functions as, for example, one NAND string NS.

The bit lines BL extend in the Y direction and are arranged in the X direction. In each string unit SU, each bit line BL is arranged to overlap at least one memory pillar MP. In the present embodiment, two bit lines BL overlap each memory pillar MP. A contact MPC is provided between one of the bit lines BL overlapping memory pillar MP and the memory pillar MP. Each memory pillar MP is electrically connected to a corresponding bit line BL via a contact MPC.

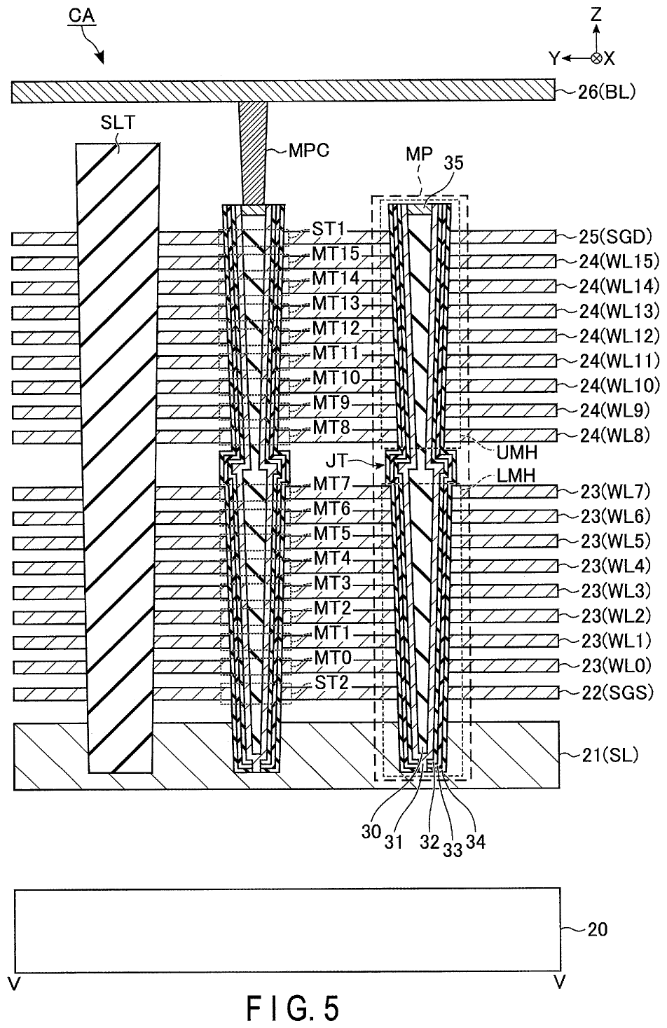

FIG. 5 is a cross-sectional view taken along line V-V of FIG. 4 and shows an example of the cross-sectional structure in cell area CA of the memory cell array 10 provided in the semiconductor memory device 1 according to the first embodiment. As shown in FIG. 5, the memory cell array 10 further includes conductive layers 21 to 26. The conductive layers 21 to 26 are provided above the semiconductor substrate 20.

Specifically, the conductive layer 21 is provided above the semiconductor substrate 20, with an insulating layer interposed. Although not shown in the drawings, the insulating layer between the semiconductor substrate 20 and the conductive layer 21 is provided with, for example, such a circuit as a sense amplifier module 16. The conductive layer 21 is formed, for example, as a plate-like shape extending in the XY plane, and is used as source line SL. The conductive layer 21 contains, for example, silicon (Si).

The conductive layer 22 is provided above the conductive layer 21, with an insulating layer interposed. the conductive layer 22 is formed, for example, as a plate-like shape extending in the XY plane, and is used as gate line SGS. The conductive layer 22 contains, for example, tungsten (W).

Insulating layers and the conductive layers 23 are alternately stacked above the conductive layers 22. Each of the conductive layers 23 is formed, for example, as a plate-like shape extending in the XY plane. For example, the stacked conductive layers 23 are respectively used as word lines WL0 to WL7 in order from the side of the semiconductor substrate 20. The conductive layers 23 contain, for example, tungsten (W).

Insulating layers and conductive layers 24 are alternately stacked above the uppermost one of the conductive layers 23. Each of the conductive layers 24 is formed, for example, as a plate-like shape extending in the XY plane. For example, the stacked conductive layers 24 are respectively used as word lines WL8 to WL15 in order from the side of the semiconductor substrate 20. The conductive layers 24 contain, for example, tungsten (W).

The insulating layer between the uppermost one of the conductive layers 23 and the lowermost one of the conductive layers 24 is thicker than the insulating layers between adjacent the conductive layers 23 and the insulating layers between adjacent conductive layers 24. In other words, the space between the uppermost one of the conductive layers 23 and the lowermost one of the conductive layers 24 in the Z direction, is larger than the spaces between adjacent conductive layers 23 and the spaces between adjacent conductive layers 24 in the Z direction.

The conductive layer 25 is provided above the uppermost one of the conductive layers 24, with an insulating layer interposed. The conductive layer 25 is formed, for example, as a plate-like shape extending in the XY plane, and is used as select gate line SGD. The conductive layer 25 contains, for example, tungsten (W).

The conductive layer 26 is provided above the conductive layer 25, with an insulating layer interposed. The conductive layer 26 is formed, for example, as a line shape extending in the Y direction, and is used as bit line BL. That is, in the region that is not shown, a plurality of the conductive layers 26 are arranged in the X direction. The conductive layers 26 contain, for example, copper (Cu).

Memory pillars MP are provided to extend in the Z direction and penetrate the conductive layers 22 to 25. Each of the memory pillars MP includes a first portion formed in the lower layer memory hole LMH, a second portion formed in the upper layer memory hole UMH, and a joint portion JT between the first portion and the second portion.

Specifically, the first portion corresponding to memory hole LMH penetrates the conductive layers 22 and 23, and the bottom thereof is in contact with the conductive layer 21. The second portion corresponding to memory hole UMH is provided above the first portion corresponding to memory hole LMH and penetrates the conductive layers 24 and 25. The joint portion JT is included in the layer between the uppermost one of the conductive layers 23 and the lowermost one of the conductive layers 24 and connects the first and second portions of the memory pillar MP. In the memory pillar MP, the outer diameter of the joint portion JT is larger than the outer diameter of the upper end of the first portion and larger than the outer diameter of the lower end of the second portion.

The memory pillar MP includes, for example, a core member 30, a semiconductor layer 31, a tunnel insulating film 32, insulating film 33, a block insulating film 34 and a semiconductor portion 35. For example, the core member 30, the semiconductor layer 31, the tunnel insulating film 32, the insulating film 33 and the block insulating film 34 are continuously provided spanning the first and second portions of the memory pillar MP.

Specifically, the core member 30 is provided to extend in the Z direction. For example, the upper end of the core member 30 is included in a layer that is upper than the layer provided with the conductive layer 25, and the lower end of the core member 30 is included in a layer provided with the conductive layer 21. The core member 30 includes, for example, an insulator such as silicon oxide (SiO₂).

The semiconductor layer 31 includes, for example, portions covering the side surface and bottom surface of the core member 30 and a columnar portion extending in the Z direction from the bottom portion of the core member 30. For example, the bottom of the columnar portion of the semiconductor layer 31 is in contact with the conductive layer 21. The semiconductor layer 31 contains, for example, silicon.

The tunnel insulating film 32 covers the side surface and the bottom surface of the semiconductor layer 31, except for the portion where the columnar portion of the semiconductor layer 31 is provided. The insulating film 33 covers the side surface and bottom surface of the tunnel insulating film 32. The block insulating film 34 covers the side surface and bottom surface of the insulating film 33. Each of the tunnel insulating film 32 and the block insulating film 34 contains, for example, silicon oxide. The insulating film 33 contains, for example, silicon nitride (SiN).

The semiconductor portion 35 is included in a layer that is upper than the conductive layer 25. For example, the side surface of the semiconductor portion 35 is in contact with the inner wall of the semiconductor layer 31, and the bottom surface thereof is in contact with the core member 30. The semiconductor portion 35 and the semiconductor layer 31 are electrically connected to each other. The semiconductor portion 35 is formed of a material similar to that of the semiconductor layer 31.

A columnar contact MPC is provided on the upper surfaces of the semiconductor layer 31 and semiconductor portion 35 which are in memory pillar MP. In the depicted region, the contact MPC corresponding to one of two memory pillars MP is shown. Although not shown, a contact MPC is connected to the memory pillar MP that is not shown as being connected to the MPC in the depicted region. One conductive layer 26, that is, one bit line BL, is in contact with the upper surface of contact MPC. One contact MPC is connected to the bit line BL in each of the spaces partitioned by the slits SLT.

The slit SLT is formed, for example, as a plate-like shape that spreads in the XZ plane, and divides the conductive layers 22 to 25. The upper end of the slit SLT is included in the layer between the conductive layer 25 and the conductive layer 26. The lower end of the slit SLT is included, for example, in a layer provided with the conductive layer 21. The slit SLT contains an insulator such as silicon oxide, for example.

In the configuration of the memory pillar MP described above, the intersection between the memory pillar MP and the conductive layer 22 functions as select transistor ST2. Each of the intersections between the memory pillar MP and the conductive layers 23, and each of the intersections between the memory pillar MP and the conductive layers 24 function as a memory cell transistor MT. The intersection between the memory pillar MP and the conductive layer 25 functions as select transistor ST1.

That is, the semiconductor layer 31 is used as channels of the memory cell transistors MT and select transistors ST1 and ST2. The insulating film 33 is used as charge storage layers of the memory cell transistors MT. Thus, each of the memory pillars MP can function as one NAND string NS.

(Configuration of Hookup Area CA of Memory Cell Array 10)

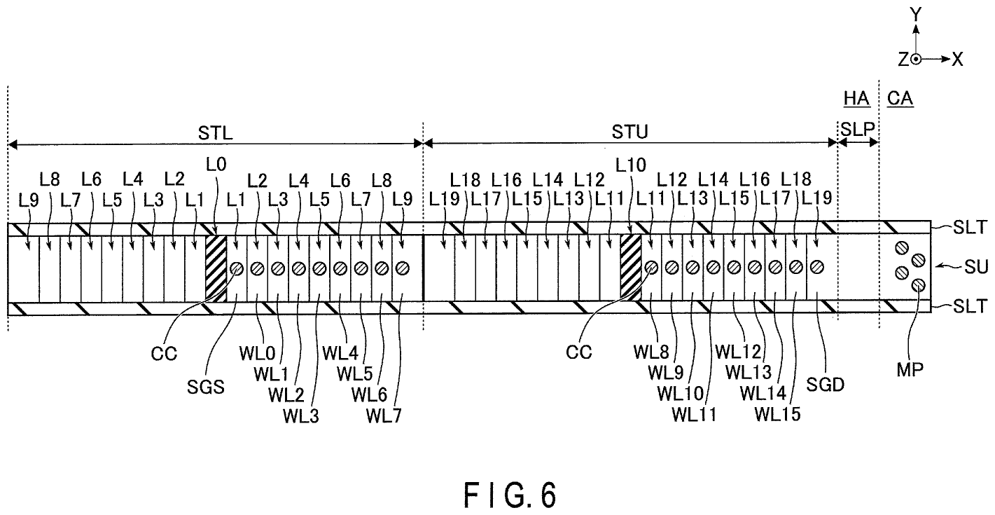

FIG. 6 shows an example of a detailed planar layout of the memory cell array 10 in the hookup area HA according to the first embodiment, and depicts an area corresponding to one string unit SU. As shown in FIG. 6, the planar layout of the memory cell array 10 in the hookup area HA is divided into, for example, a lower layer connection area STL, an upper layer connection area STU, and a sloping area SLP, as viewed in the X direction. The memory cell array 10 includes a plurality of contacts CC in the hookup area HA.

The lower layer connection area STL is an area in which contacts CC are provided for connecting the conductive layers 22 and 23, through which memory hole LMH extends, to the row decoder module 15. Specifically, the lower layer connection area STL includes levels L0 to L9. Levels L1 to L9 are provided stepwise on each side of level L0 and are arranged in the X direction. Level L1 corresponds to select gate line SGS. Levels L2 to L9 correspond to word lines WL0 to WL7, respectively.

The upper layer connection area STU is an area in which contacts CC are provided for connecting the conductive layers 24 and 25, through which memory hole UMH extends, to the row decoder module 15. Specifically, the upper layer connection area STU includes levels L10 to L19. Levels L11 to L19 are provided stepwise on each side of level L10 and are arranged in the X direction. The height of level L10 is, for example, the same as level L9 of the lower layer connection area STL. Levels L11 to L18 correspond to word lines WL8 to WL15, respectively. Level L19 corresponds to select gate line SGD.

The sloping area SLP is disposed between the cell area CA and the lower and upper layer connection areas STL and STU. In other words, in the hookup area HA, the sloping area SLP is located in the vicinity of the cell area CA. In the semiconductor memory device 1 according to the first embodiment, the interconnect layer to which the contacts CC are connected in the upper layer connection area STU has a bent structure (sloping structure) in the sloping area SLP.

A plurality of contacts CC are respectively provided, for example, such that they correspond levels L1 to L9 which are provided on the cell area CA side of the lower layer connection area STL and levels L11 to L19 which are provided on the cell area CA side of the upper layer connection area STU. That is, select gate line SGS is electrically connected to the contact CC corresponding to level L1. The word lines WL0 to WL7 are electrically connected to the contacts CC respectively corresponding to levels L2 to L9. The word lines WL8 to WL15 are electrically connected to the contacts CC respectively corresponding to levels L11 to L18. The select gate line SGD is electrically connected to the contact CC corresponding to level L19.

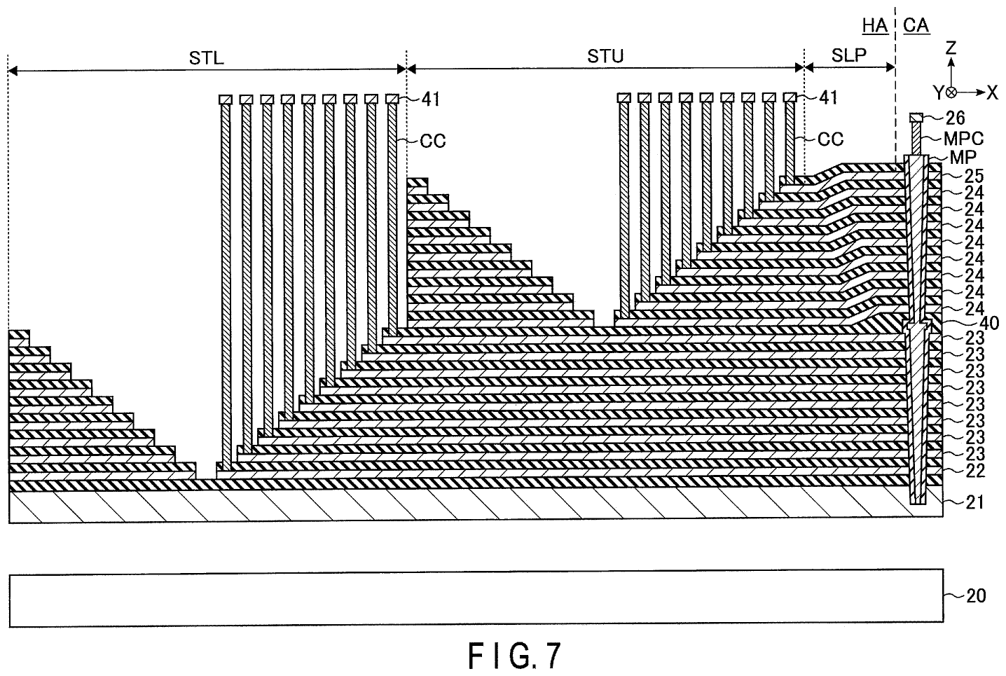

FIG. 7 shows an example of the cross-sectional structure of the memory cell array 10 in the hookup area HA according to the first embodiment. In the cross-sectional views referred to in the description below and including the hookup area HA, the configuration of the memory pillar MP is shown in a simplified manner. As shown in FIG. 7, the hookup area HA of the memory cell array 10 has the staircase configuration and sloping configuration described with reference to FIG. 6. The memory cell array 10 further includes insulating layers 40 and conductive layers 41.

The end portions of the conductive layers 22 to 25 corresponding to the select gate line SGS, the word lines WL0 to WL15 and the select gate line SGD are led from the cell area CA toward the hookup area HA. Each of the conductive layers 22 to 25 corresponding to the select gate line SGS, the word lines WL0 to WL15 and the select gate line SGD has a terrace portion that does not overlap an upper conductive layer. For example, the terrace portions of the conductive layers 22 and 23 are included in the lower layer connection area STL. The terrace portions of the conductive layers 24 and 25 are included in the upper layer connection area STU.

The terrace portions shown in FIG. 7 correspond to levels L1 to L9 and L11 to L19 shown in FIG. 6, respectively. Specifically, the terrace portion of the conductive layer 22 corresponds to level L1. The terrace portions of the eight conductive layers 23 correspond to levels L2 to L9, respectively. The terrace portions of the eight conductive layers 24 correspond to levels L11 to L18, respectively. The terrace portion of the conductive layer 25 corresponds to level L19.

The insulating layer 40 is provided between the uppermost one of the conductive layers 23 and the lowermost one of the conductive layers 24. In the sloping area SLP, the thickness of the insulating layer 40 decreases from the cell area CA to the hookup area HA. For this reason, the insulating layer 40 located in the cell area CA is thicker than the insulating layer 40 located in the upper layer connection area STU. The thickness of the insulating layer 40 located in the upper layer connection area STU is substantially equal to the thickness of the insulating layer provided between adjacent conductive layers 23 and to the thickness of the insulating layer provided between adjacent conductive layers 24.

In the sloping area SLP, the conductive layers 24 and 25 corresponding to upper layer connection area STU are provided along the portion where the thickness of the insulating layer 40 changes. The thickness of each of the conductive layers 24 and 25 is substantially constant in the cell area CA and the hookup area HA. For this reason, each of the conductive layers 24 and 25 in the sloping area SLP has a bent portion (inclined structure). In other words, in the sloping area SLP, the insulating layer 40 has a sloping portion on its upper surface, and each of the conductive layers 24 and 25 has a sloping portion that is along the sloping upper surface of the insulating layer 40.

Columnar contacts CC are provided on the terrace portions of respective conductive layers 22 to 25. The conductive layers 41 are provided on the respective contacts CC. Each conductive layer 41 is provided, for example, in a layer that is upper than the conductive layer 26 and is electrically connected to the row decoder module 15 through a region that is not shown. That is, each of the conductive layers 22 to 25 is electrically connected to the row decoder module 15 by way of the corresponding contact CC and conductive layer 41.

As described above, in the hookup area HA, the memory cell array 10 has a concave staircase structure in each of the lower layer connection area STL and upper layer connection area STU. The contacts CC included in the lower layer connection area STL are connected to the end portions of the conductive layers 22 or 23 that are continuous from the conductive layers 22 or 23 located in the cell area CA. The contacts CC included in the upper layer connection area STU are connected to the end portions of the conductive layers 24 or 25 that are continuous from the conductive layers 24 or 25 located in the cell area CA.

Each of the lower layer connection area STL and the upper layer connection area STU includes, for example, a staircase portion to which the contacts CC are not connected. For example, in the region between the contact CC connected to the uppermost one of the conductive layers 23 and the contact CC connected to the lowermost one of the conductive layers 24, a plurality of conductive layers insulated from the conductive layers 24 and 25 and located in the same layers as the conductive layers 24 and 25 are provided stepwise.

The configuration of the memory cell array 10 described above is merely an example, and the memory cell array 10 may have other configurations. For example, the number of conductive layers 23 and 24 is designed based on the number of word lines WL. A plurality of conductive layers 22 that are provided in a plurality of layers may be assigned to select gate line SGS. Where the select gate line SGS is provided in a plurality of layers, different conductors may be used in different interconnect layers. A plurality of conductive layers 25 provided in a plurality of layers may be assigned to conductive layer 25 corresponding to select gate line SGD.

### [1-2] Manufacturing Method of Semiconductor Memory Device 1

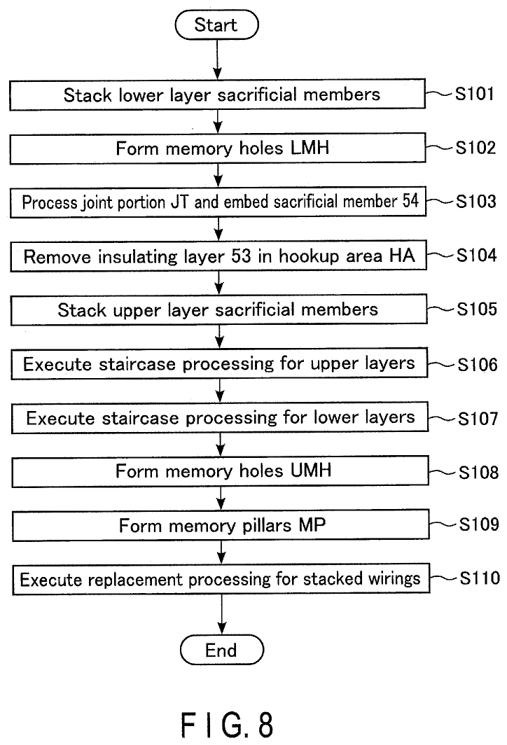

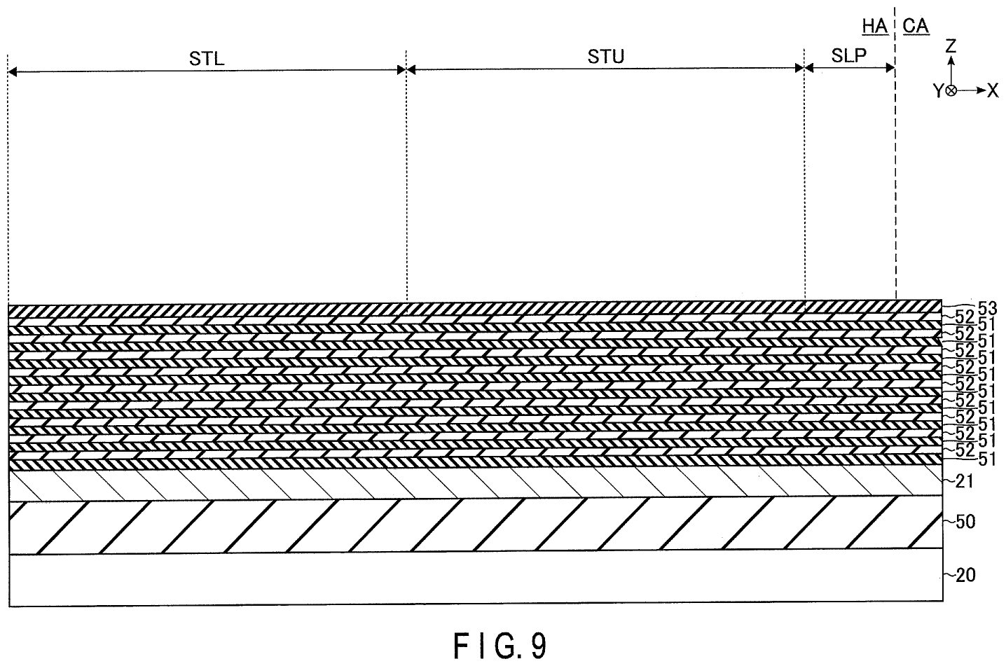

Hereinafter, with reference to FIG. 8 as appropriate, a description will be given of an example of a series of manufacturing steps in which a stacked structure corresponding to word line WL is formed in the semiconductor memory device 1 according to the first embodiment. FIG. 8 is a flowchart illustrating an example of a method of manufacturing the semiconductor memory device 1 according to the first embodiment. Each of FIGS. 9 to 22 shows an example of a cross sectional structure or a planar layout including the structure corresponding to the memory cell array 10 in the manufacturing steps of the semiconductor memory device 1 according to the first embodiment. The plan views in the manufacturing steps to be referred to in the description below show an area corresponding to FIG. 6, and the sectional views show an area corresponding to FIG. 7.

First, as shown in FIG. 9, lower layer sacrificial members are stacked in the process of step S101. The lower layer sacrificial members correspond to stacked wirings through which memory hole LMH is made to pass in the subsequent process. In the present process, first, an insulating layer 50 and a conductive layer 21 are sequentially stacked on the semiconductor substrate 20. Although not shown in the drawings, a circuit corresponding to the sense amplifier module 16 or the like is formed in the insulating layer 50. Subsequently, insulating layers 51 and sacrificial members 52 are alternately stacked on the conductive layer 21, and an insulating layer 53 is formed on the uppermost one of the sacrificial members 52.

The conductive layer 21 is used as source line SL. The conductive layer 21 contains, for example, silicon (Si). Each of the insulating layers 51 and 53 contains, for example, silicon oxide (SiO₂). For example, the number of layers in which the sacrificial members 52 are formed corresponds to the number of select gate lines SGS and word lines WL through which memory holes LMH pass. The sacrificial members 52 contain, for example, silicon nitride (SiN).

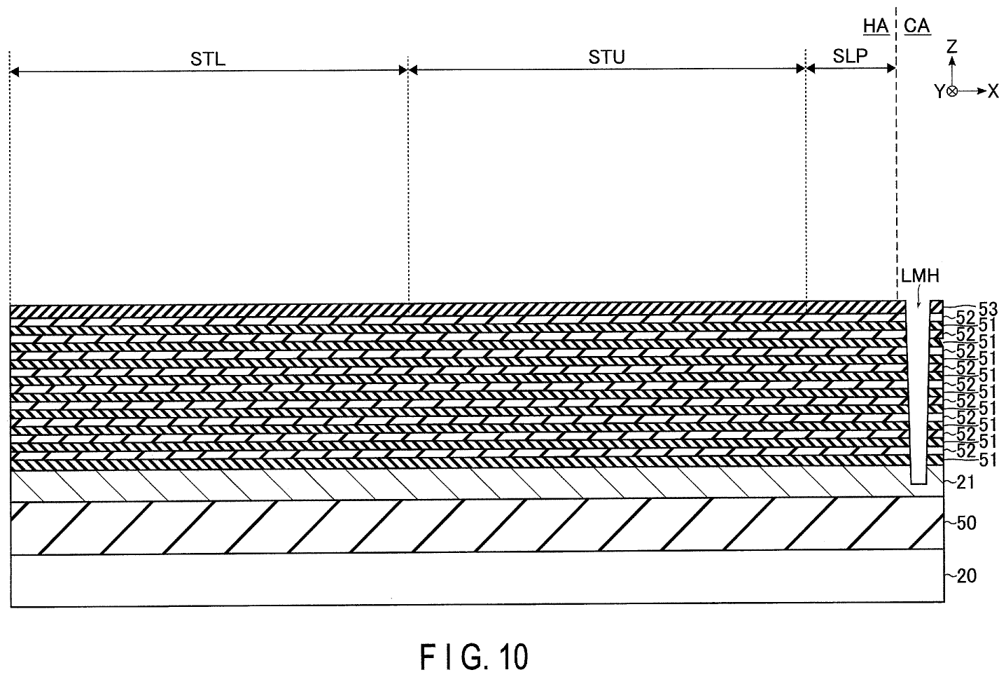

Next, as shown in FIG. 10, the process of step S102 is executed to form a memory hole LMH. Specifically, a mask having an opening in the region corresponding to the memory hole LMH is first formed by photolithography or the like. Then, the memory hole LMH is formed by anisotropic etching using the formed mask. In plan view, a plurality of memory holes LMH are arranged, for example, in a staggered manner.

The memory holes LMH formed in the present process pass through the insulating layers 51 and 53 and the sacrificial members 52, and the bottoms of the memory holes LMH end, for example, in the conductive layer 21. The anisotropic etching used in this process is, for example, RIE (Reactive Ion Etching).

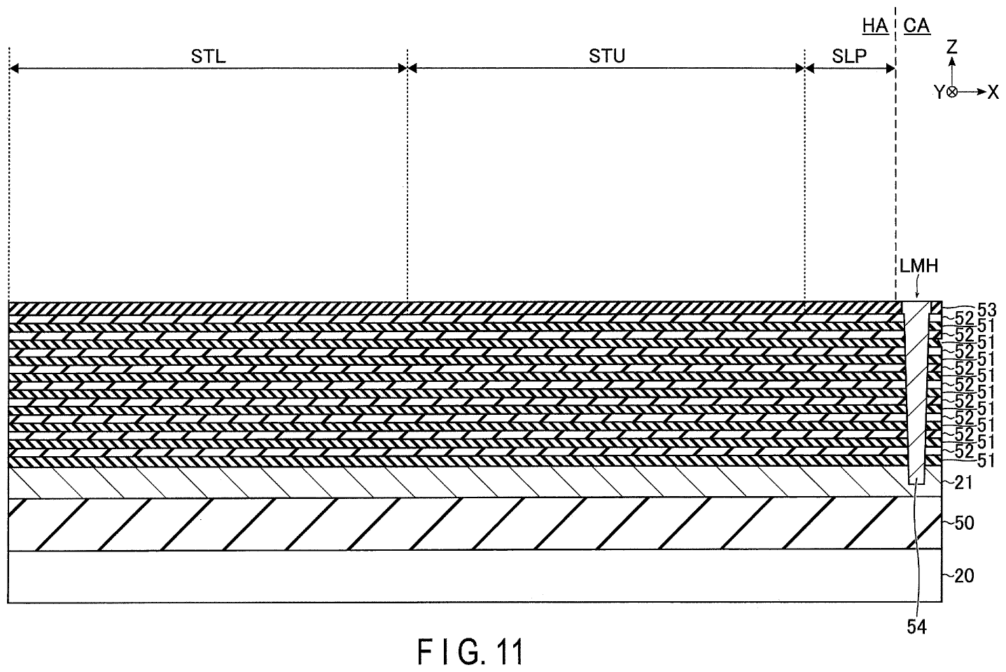

Next, as shown in FIG. 11, the joint portion JT is processed and a sacrificial member 54 is embedded in the process of step S103. Specifically, a sacrificial member 54 first is formed in the memory hole LMH such that the sacrificial member 54 has the same height as the uppermost one of the insulating layers 51. Then, the insulating layer 53 is isotropically etched by wet etching, for example, such that the diameter of the upper portion of the memory hole LMH becomes larger.

Thus, an opening corresponding to the joint portion JT is formed above the memory hole LMH. In the following description of the manufacturing process, it is assumed for the simplicity of description that the memory hole LMH includes the joint portion JT. Thereafter, the sacrificial member 54 is embedded in the opening corresponding to the joint portion JT. As a result, a structure in which the sacrificial member 54 is embedded in the memory hole LMH is formed.

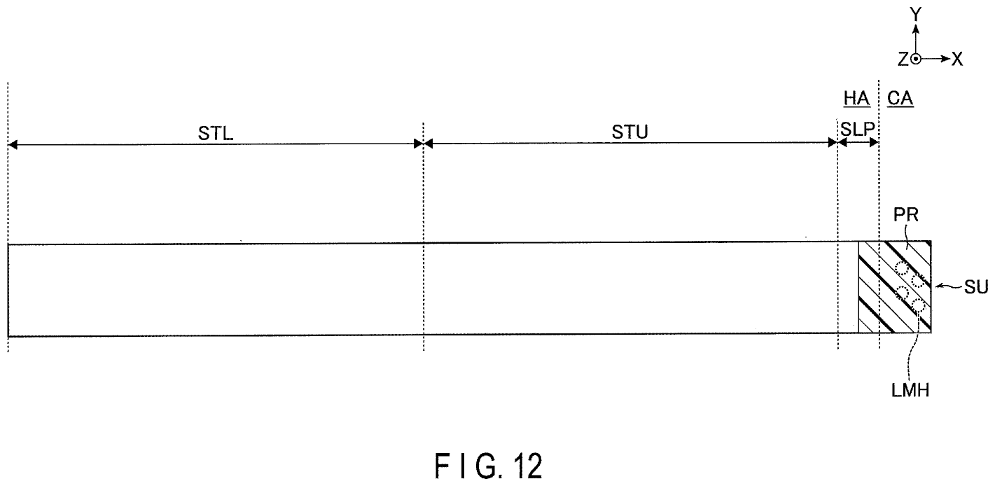

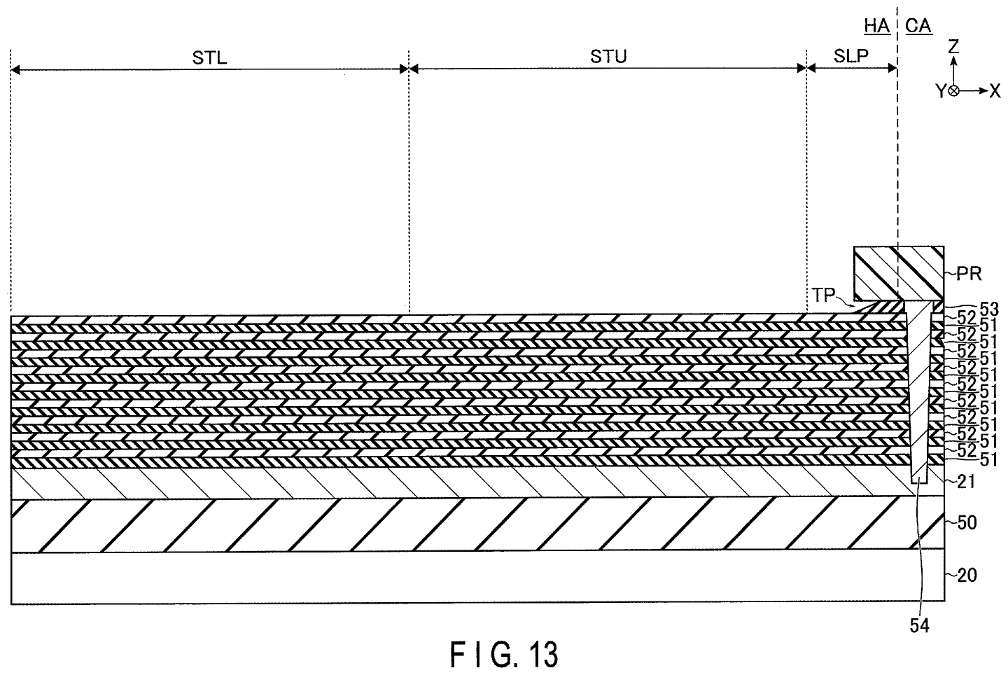

Next, as shown in FIGS. 12 and 13, the insulating layer 53 in the hookup area HA is removed in the process of step S104. Specifically, a mask PR which covers the cell area CA and part of the sloping area SLP in the hookup area HA is first formed by photolithography or the like. The mask PR is, for example, a photoresist.

Then, isotropic etching is performed using the formed mask PR. Thus, in the hookup area HA, the insulating layer 53 provided for the lower layer connection area STL and upper layer connection area STU is removed. On the other hand, in the sloping area SLP, part of insulating layer 53 corresponding to the lower portion of the end of the mask PR is removed in accordance with the etching progress, and the insulating layer 53 is made to have a sloping portion TP. The mask PR used in this process is removed after the processing of the insulating layer 53 is completed.

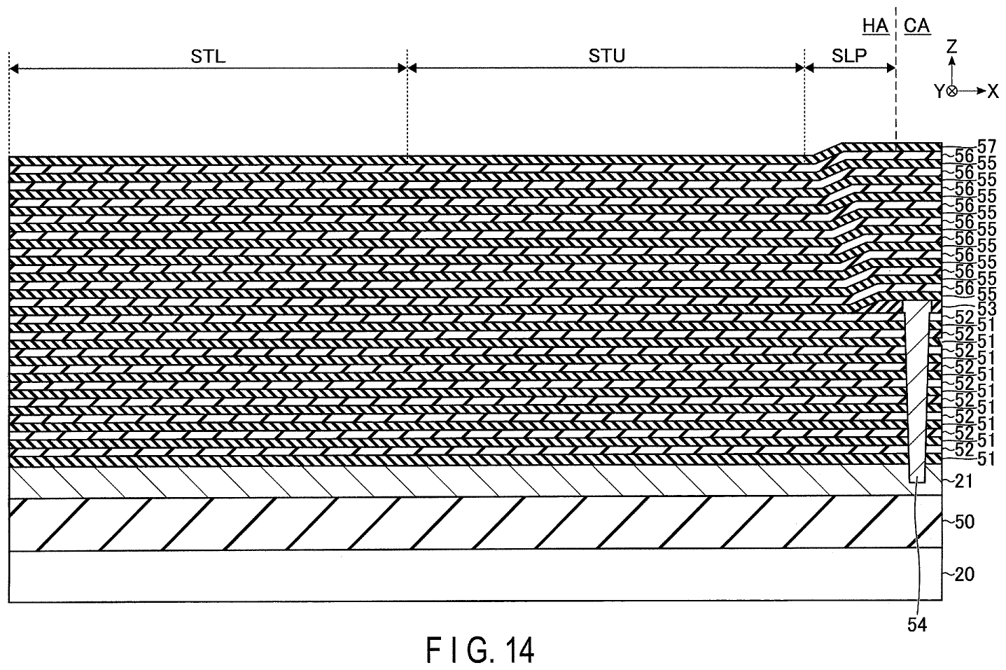

Then, as shown in FIG. 14, upper layer sacrificial members are stacked in the process of step S105. The upper layer sacrificial members correspond to stacked wirings through which memory hole UMH is made to pass in the subsequent process. In the present process, insulating layers 55 and sacrificial members 56 are alternately stacked on the exposed portions of the uppermost one of the sacrificial members 52 and insulating layer 53, and an insulating layer 57 is formed on the uppermost one of the sacrificial members 56. As a result, in the sloping area SLP, stacked insulating layers 55 and 57 and sacrificial members 56 are formed along the sloping portion TP of insulating layer 53.

Each of the insulating layers 55 and 57 contains, for example, silicon oxide. For example, the number of layers in which the sacrificial members 56 are formed corresponds to the number of select gate lines SGD and word lines WL through which memory holes UMH pass. The sacrificial members 56 are formed of a material similar to that of the sacrificial members 52, and contain, for example, silicon nitride. The lowermost one of the insulating layers 55 and insulating layer 53, which are formed in the present process, correspond to insulating layer 40 described with reference to FIG. 7.

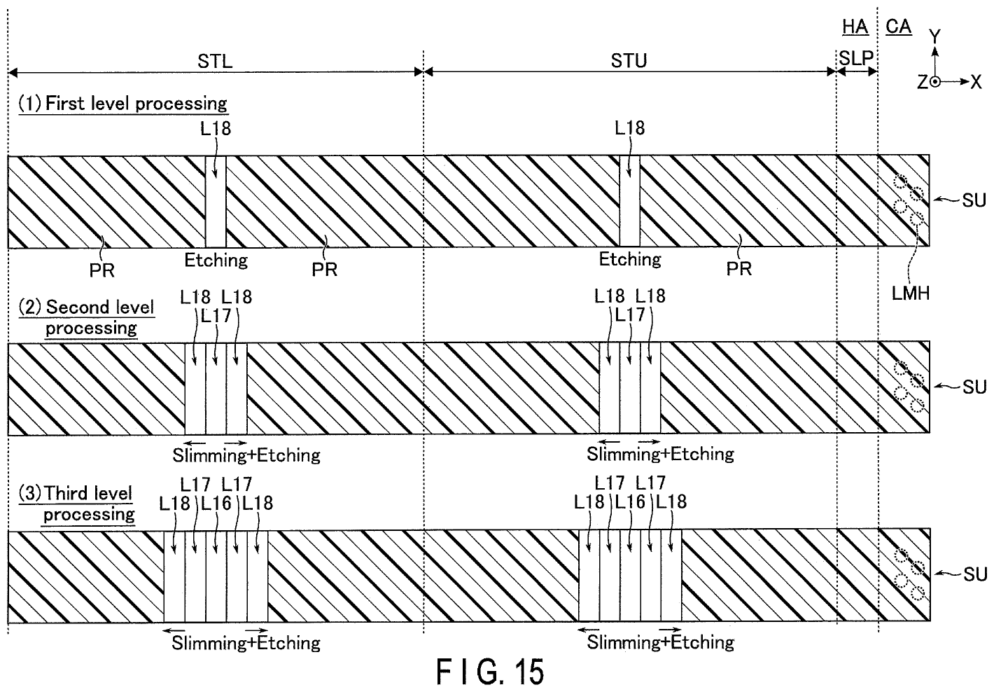

Next, as shown in FIG. 15, the process of step S106 is performed to execute staircase processing for the upper layers. Specifically, a mask PR in which regions corresponding to levels L0 and L10 in FIG. 6 are open is first formed by photolithography or the like. Then, the insulating layer 57 and the sacrificial member 56 are processed by one level by anisotropic etching, and level L18 is formed in the opening portions of the mask PR, as shown in FIG. 15(1) (first level processing).

Thereafter, a slimming process is performed for the mask PR such that the regions corresponding to levels Ll and L11 shown in FIG. 6 are exposed. Subsequently, the insulating layer 55 or 57 and the sacrificial member 56 are processed by one level by anisotropic etching to form levels L17 and L18 in the opening portions of the mask PR, as shown in FIG. 15(2) (second level processing).

Thereafter, a slimming process is performed for the mask PR such that the regions corresponding to levels L2 and L12 shown in FIG. 6 are exposed. Subsequently, the insulating layer 55 or 57 and the sacrificial member 56 are processed by one level by anisotropic etching, and levels L16, L17 and L18 are formed in the opening portions of the mask PR, as shown in FIG. 15(3) (third level processing).

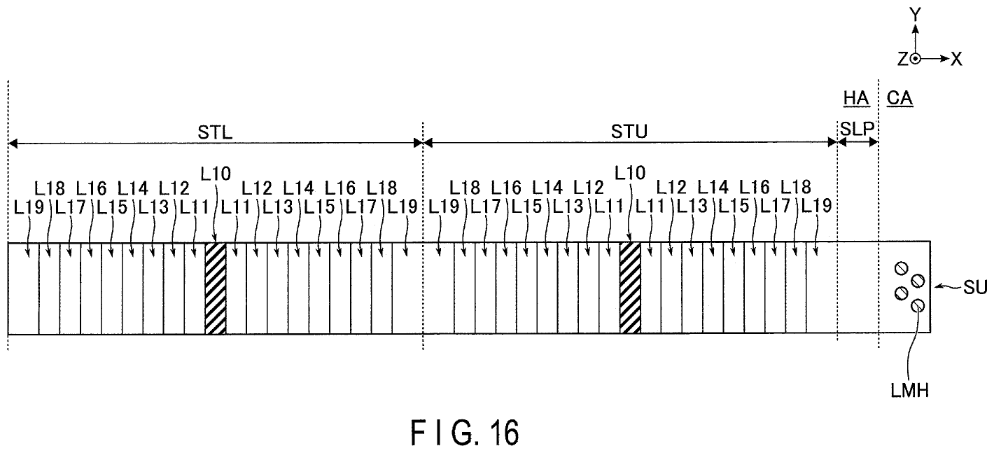

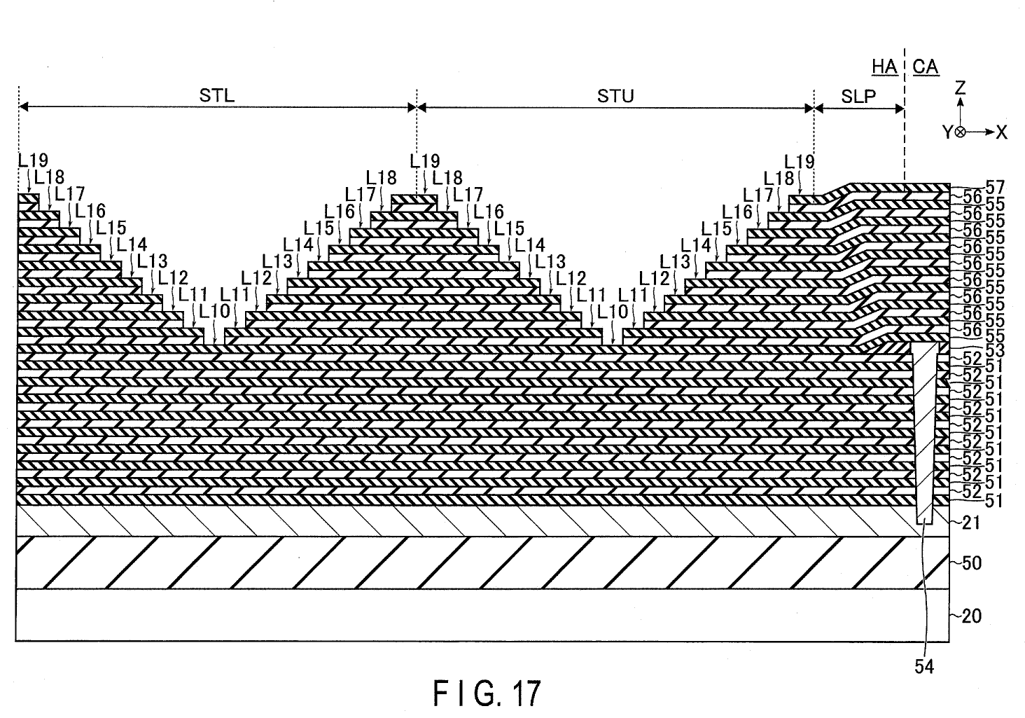

Likewise, the combination of the slimming process of the mask PR and the anisotropic etching of the stacked structure is repeatedly performed until level L10 is formed. Then, the mask PR used in the present process is removed after completion of the staircase processing of the upper layers. Thereby, as shown in FIG. 16 and FIG. 17, levels L10 to L19 are formed. More specifically, levels L11 to L19 are provided stepwise on both sides of level L10 in the X direction in each of lower layer connection area STL and upper layer connection area STU.

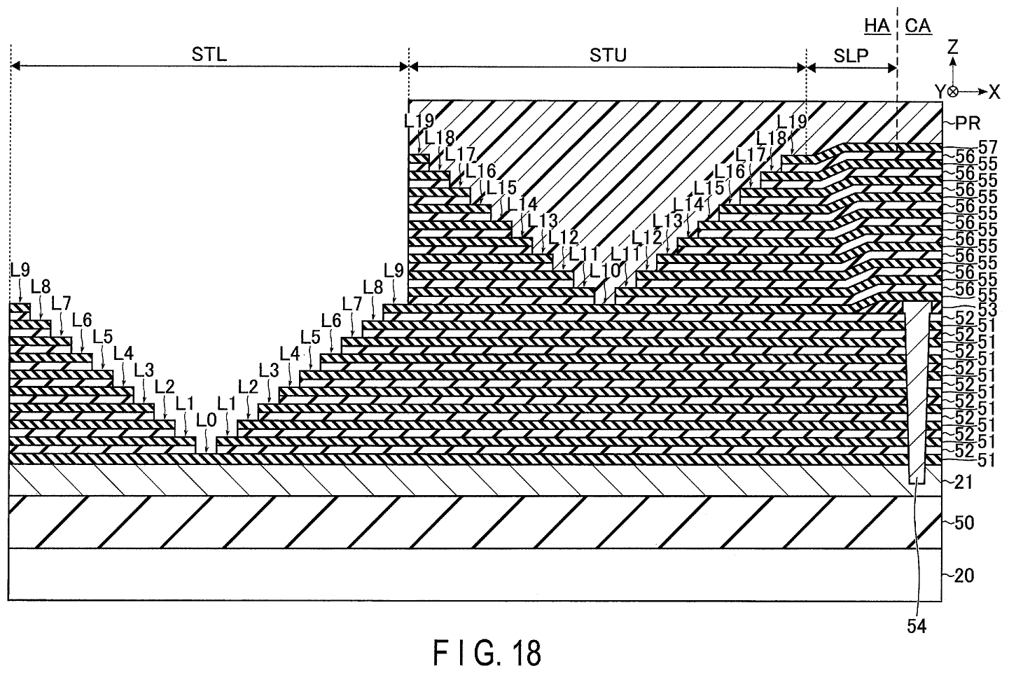

Next, as shown in FIG. 18, the process of step S107 is performed to execute staircase processing for the lower layers. Specifically, a mask PR in which the lower layer connection area STL is exposed is first formed by photolithography or the like, and anisotropic etching is subsequently performed. In the present process, in the lower layer connection area STL, etching is performed until the portion where level L10 is formed before processing reaches level L0. Thereby, levels L0 to L9 are formed. More specifically, in the lower layer connection area STL, levels L1 to L9 are provided stepwise on both sides of level L0 in the X direction. The mask PR used in the present process is removed after completion of the staircase processing of the lower layers.

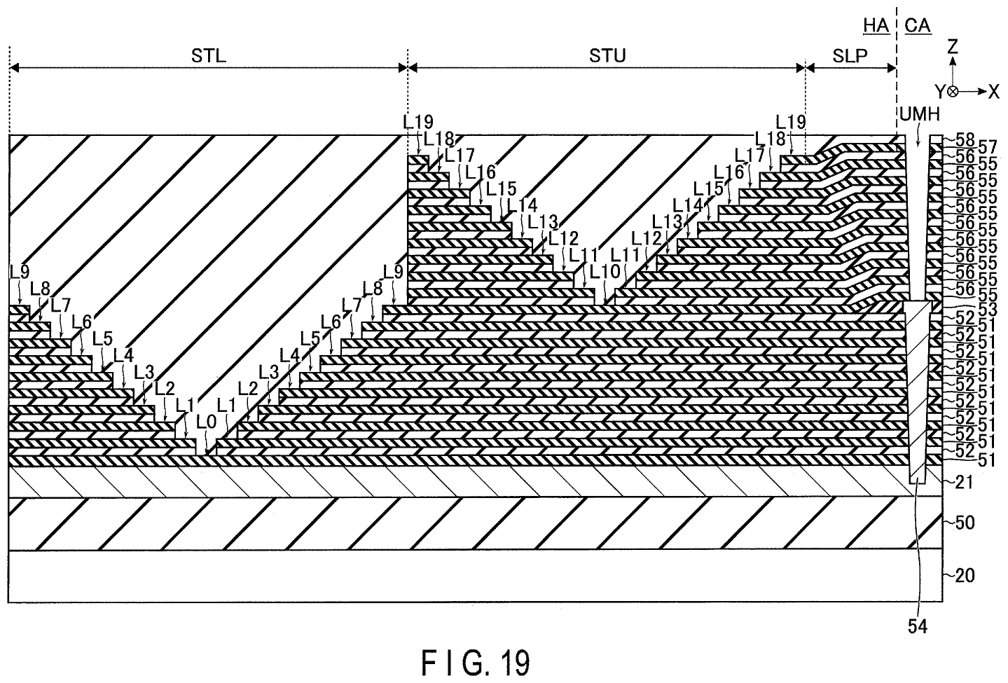

Next, as shown in FIG. 19, the process of step S108 is executed to form memory hole UMH. Specifically, an insulating layer 58 is first formed, and the staircase portion formed in each of the lower layer connection area STL and upper layer connection area STU is covered with the insulating layer 58. Then, the upper surface of the insulating layer 58 is made flat by, for example, CMP (Chemical Mechanical Polishing).

Thereafter, a mask having an opening in the region corresponding to memory hole UMH is formed by photolithography or the like. Then, memory hole UMH is formed by anisotropic etching using the formed mask. In plan view, a plurality of memory holes UMH formed overlap respective memory holes LMH. That is, in the present process, the sacrificial member 54 formed in memory hole LMH is exposed at the bottom of memory hole UMH.

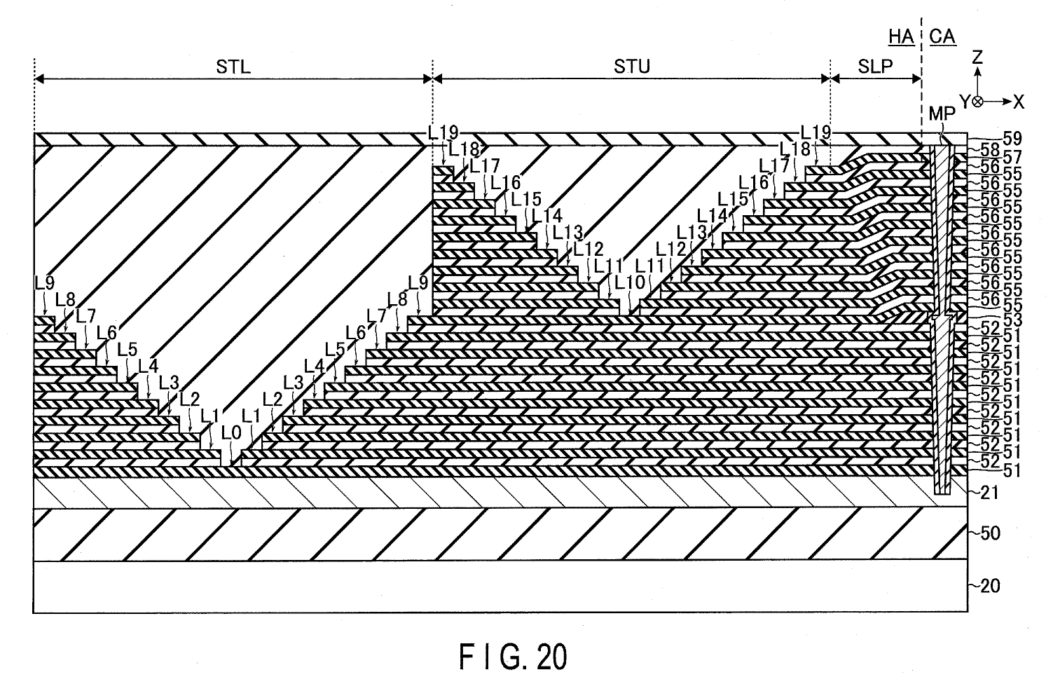

Next, as shown in FIG. 20, the process of step S109 is executed to form a memory pillar MP. Specifically, the sacrificial member 54 in memory hole LMH is first removed via memory hole UMH. Thereby, a memory hole in the shape of memory pillar MP is formed. Then, a block insulating film 34, an insulating film 33 and a tunnel insulating film 32 are sequentially formed on the side and bottom surfaces of the memory hole and on the upper surface of the insulating layer 58.

After the block insulating film 34, the insulating film 33 and the tunnel insulating film 32, which are at the bottom of the memory hole, are removed, a semiconductor layer 31 and a core member 30 are sequentially formed, and the inside of the memory hole is filled with the core member 30. Then, part of the core member 30 formed in the upper portion of the memory hole is removed, and a semiconductor material (semiconductor portion 35) is embedded in the resultant space. Thereafter, the block insulating film 34, the insulating film 33, the tunnel insulating film 32, the semiconductor layer 31 and the semiconductor material, which remain above the insulating layer 58, are removed.

Thus, a structure corresponding to the memory pillar MP is formed in the memory hole. After the memory pillar MP is formed, for example, an insulating layer 59 is formed on the upper surface of the memory pillar MP and on the insulating layer 58. The insulating layer 59 contains, for example, silicon oxide.

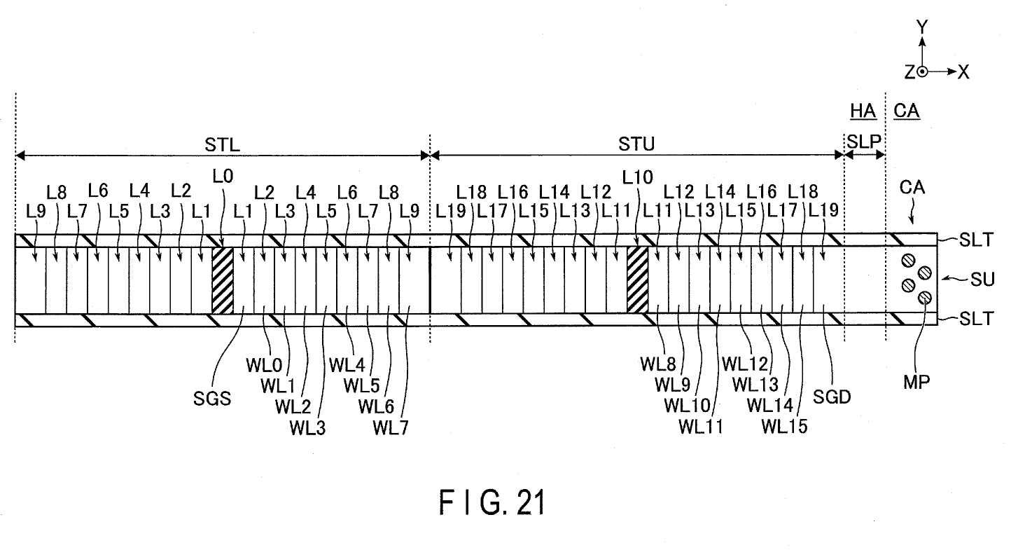

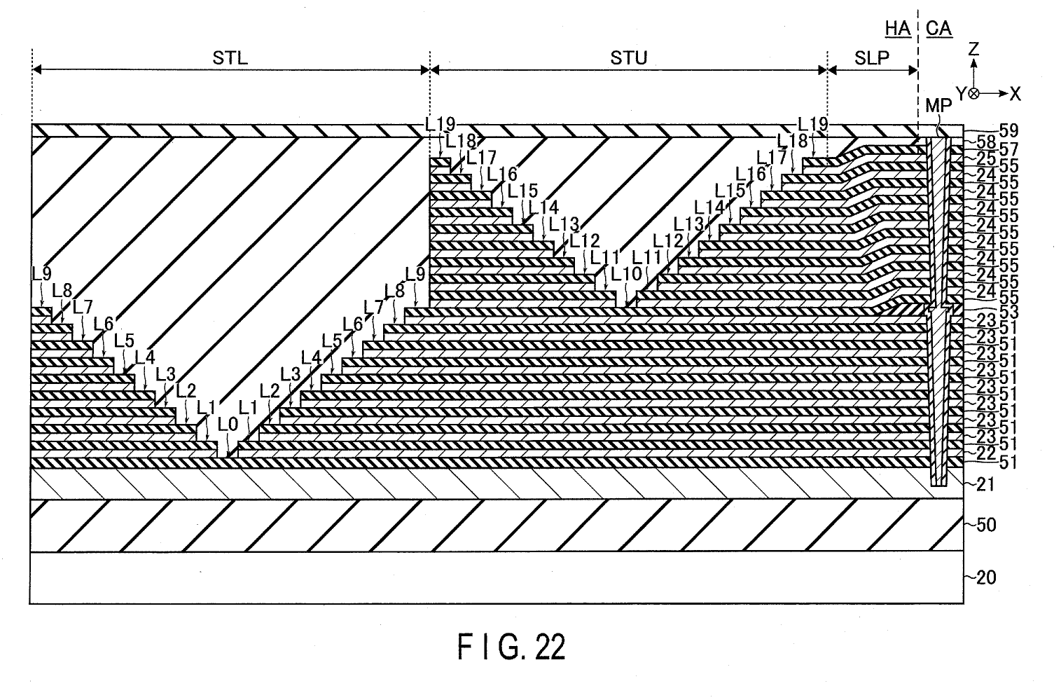

Next, as shown in FIGS. 21 and 22, the process of step S110 is performed to execute replacement processing for stacked wirings is performed. Specifically, a mask having an opening in the region corresponding to a slit SLT is first formed by photolithography or the like. Then, the slit SLT is formed by anisotropic etching using the formed mask. The slit SLT formed in the present process divides the insulating layers 51, 53, 55, 57 58 and 59 and the sacrificial members 52 and 56, and the bottom of the slit SLT ends inside the layer in which the conductive layer 21 is provided. The slit SLT is formed, for example, in such a manner that the bottom of the slit SLT reaches at least the layer in which the conductive layer 21 is formed. The anisotropic etching used in the present process is, for example, RIE.

The sacrificial members 52 and 56 are selectively removed via the slit SLT by wet etching using, for example, hot phosphoric acid. The structure from which the sacrificial members 52 and 56 are removed maintains its three-dimensional structure by a plurality of memory pillars MP and the like. Then, a conductor is embedded in the space from which the sacrificial members 52 and 56 are removed via the slit SLT. In the present process, CVD is used to form the conductor. Thereafter, the conductor formed in the slit SLT and on the upper surface of the insulating layer 59 is removed by an etch back process. In the present process, conductors formed in the adjacent interconnect layers may be separated at least in the slits SLT.

In this manner, a conductive layer 22 corresponding to the select gate line SGS, a plurality of conductive layers 23 respectively corresponding to the word lines WL0 to WL7, a plurality of conductive layers 24 respectively corresponding to the word lines WL8 to WL15, and a conductive layer 25 corresponding to the select gate line SGD are formed. The conductive layers 22 to 25 formed in the present process may contain a barrier metal. In this case, in the conductor formation process executed after the removal of the sacrificial members 52 and 56, tungsten is formed, for example, after a film of titanium nitride is formed as a barrier metal. The slits SLT used in the present process are filled with an insulator after the stacked wirings are formed.

In the above-mentioned manufacturing processes of the semiconductor memory device 1 according to the first embodiment, the memory pillar MP, the source line SL connected to the memory pillar MP, the word line WL and the select gate lines SGS and SGD are formed. Then, in the subsequent manufacturing process, a plurality of contacts CC respectively connected to word lines WL and select gate lines SGS and SGD are formed using levels L1 to L9 and L11 to L19 formed in the above manufacturing processes. The manufacturing processes described above is merely an example, and other processes may be executed between the respective manufacturing processes, or the order in which to execute the manufacturing processes may be changed as long as no problem occurs.

### [1-3] Advantageous Effects of First Embodiment

The semiconductor memory device 1 according to the first embodiment described above can suppress defects which may be caused by the contacts CC, and the manufacturing yield can be improved. Detailed advantageous effects of the semiconductor memory device 1 according to the first embodiment will be described.

In a semiconductor memory device in which memory cells are three-dimensionally stacked, plate-like wirings which are used, for example, as word lines WL are stacked, and a structure functioning as memory cell transistors MT is formed in a memory pillar penetrating the stacked wirings. The stacked word lines WL are led out in the form of a staircase, for example, at end portions, and the staircase region is provided with contacts for electrically connecting the word lines WL to the row decoder module.

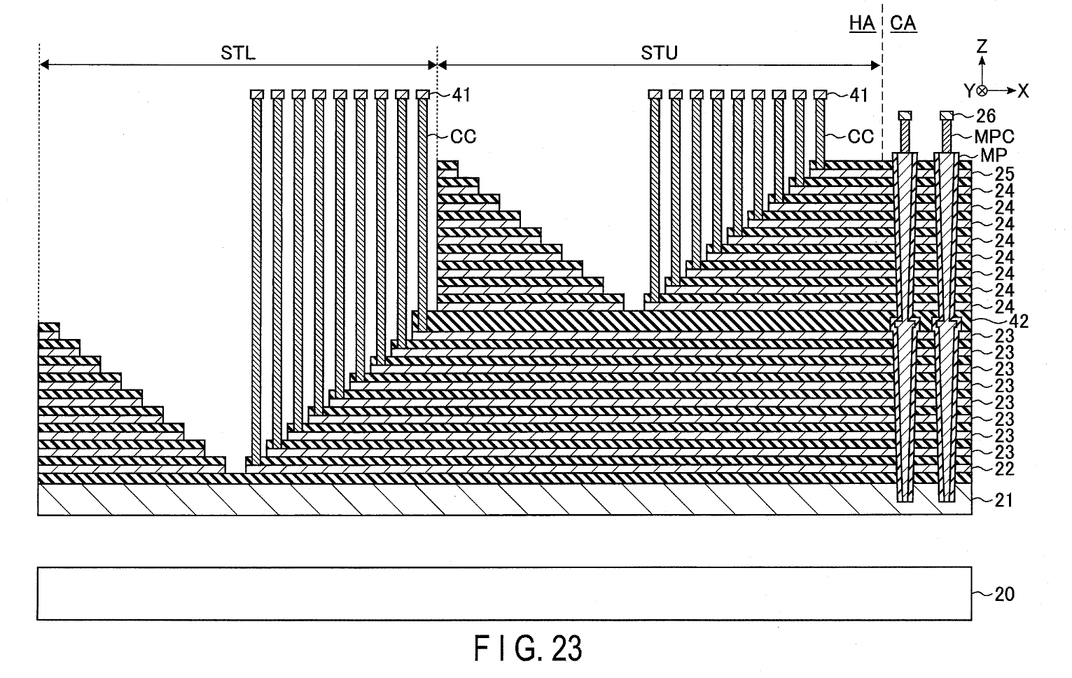

In a semiconductor memory device in which memory cells are three-dimensionally stacked, a memory pillar in which two or more pillars are connected in the Z direction may be formed as the number of word lines WL stacked increases. In the portion where the pillars are connected, an interlayer insulating film that is thicker than an interlayer insulating film between interconnect layers adjacent in other portions may be formed. An example of the cross-sectional structure in the hookup area HA of such a semiconductor memory device is shown in FIG. 23. FIG. 23 shows an example of the cross-sectional structure of a memory cell array 10 according to a comparative example of the first embodiment, and depicts the region corresponding to that shown in FIG. 7 referred to in connection with the first embodiment.

As shown in FIG. 23, the configuration of the memory cell array 10 of the comparative example of the first embodiment differs from the configuration of the memory cell array described in connection with the first embodiment, in that the sloping area SLP is not provided and the configuration between the uppermost one of the conductive layers 23 and the lowermost one of the conductive layer 24 is different. Specifically, in the memory cell array 10 of the comparative example of the first embodiment, the insulating layer 42 is provided between the uppermost one of the conductive layers 23 and the lowermost one of the conductive layers 24. The insulating layer 42 has a substantially uniform thickness from the cell area CA to the upper layer connection area STU in the hookup area HA.

That is, in the upper layer connection area STU of the memory cell array 10 according to the comparative example of the first embodiment, the insulating layer 42 between the uppermost one of the conductive layers 23 and the lowermost one of the conductive layers 24 is thicker than the insulating layer between adjacent conductive layers 23 and the insulating layer between adjacent conductive layers 24. In other words, the hookup area HA of the memory cell array 10 according to the comparative example of the first embodiment includes a portion in which the distance between the insulating layers differs.

Therefore, the configuration of the memory cell array 10 according to the comparative example of the first embodiment has problems in that the etching property inevitably varies due to the influence of the insulating layer 42 in the case where a concave staircase structure is formed in each of the upper layer connection area STU and the lower layer connection area STL, and then the concave staircase structure of the lower layer connection area STL is collectively processed to the lowermost layer, as in steps S106 and S107 described in connection with the first embodiment. That is, in the configuration of the memory cell array 10 according to the comparative example of the first embodiment, the contacts CC may have defects due to the characteristic variations in the staircase structure of the lower layer connection area STL.

On the other hand, the semiconductor memory device 1 according to the first embodiment has the sloping area SLP in the hookup area HA of the memory cell array 10. The lowermost one of the conductive layers 24 included in the upper layer connection area STU is inclined in the sloping area SLP, and is adjacent to the uppermost one of the conductive layers 23, with insulating layer 40 interposed, in the upper layer connection area STU. That is, in the memory cell array 10 of the first embodiment, the spaces between the insulating layers are substantially equal at the end portions of the stacked wirings in the hookup area HA.

Therefore, in the manufacturing method of the semiconductor memory device 1 according to the first embodiment, etching property variations due to the influence of insulating layer 40 can be suppressed in the case where a concave staircase structure is formed in each of the upper layer connection area STU and the lower layer connection area STL, and then the concave staircase structure of the lower layer connection area STL is collectively processed to the lowermost layer, as in steps S106 and S107.

As a result, in the method of manufacturing the semiconductor memory device 1 according to the first embodiment, defects in the contacts CC due to characteristic variations in the staircase structure of the lower layer connection area STL can be suppressed. That is, the semiconductor memory device 1 according to the first embodiment can suppress defects which may be caused by the contacts CC, and the manufacturing yield can be improved.

### 2 Second Embodiment

The semiconductor memory device 1 according to the second embodiment differs from the semiconductor memory device 1 according to the first embodiment in that in the hookup area HA, a dummy word line is added to the layer corresponding to the joint portion JT. A description will be given of the points in which the semiconductor memory device 1 of the second embodiment differs from that of the first embodiment.

### [2-1] Configuration of Memory Cell Array 10

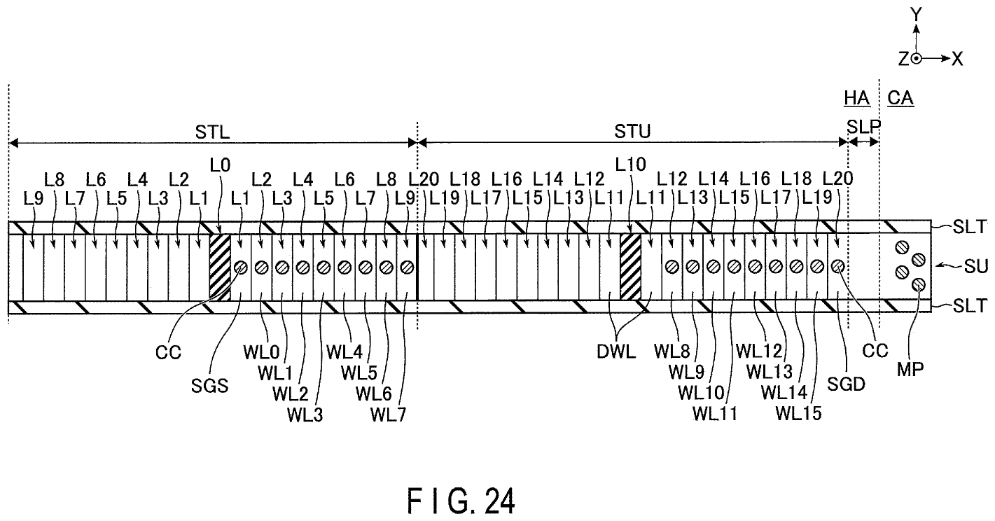

FIG. 24 shows an example of a planar layout of the memory cell array 10 in the hookup area HA according to the second embodiment. As shown in FIG. 24, the planar layout of the memory cell array 10 in the hookup area HA of the second embodiment differs from the planar layout of the memory cell array 10 described with reference to FIG. 6 in connection with the first embodiment, in terms of the number of levels provided in the upper layer connection area STU.

Specifically, the upper layer connection area STU in the second embodiment includes levels L10 to L20. Levels L11 to L20 are provided stepwise in the X direction on each side of level L10. The height of level L10 is, for example, the same as level L9 of the lower layer connection area STL. Level L11 corresponds to the dummy word line DWL. The dummy word line DWL is a wiring that is not connected to the NAND string NS. Levels L12 to L19 correspond to the word lines WL8 to WL15, respectively. Level L20 corresponds to the select gate line SGD.

A plurality of contacts CC are provided, for example, such that they correspond to levels L12 to L20 provided on the cell area CA side in the upper layer connection area STU. That is, in the second embodiment, the word lines WL8 to WL15 are electrically connected to the contacts CC corresponding to levels L12 to L19, respectively. The select gate line SGD is electrically connected to the contact CC corresponding to level L20. In the second embodiment, a contact CC may be connected, or may not be connected to the dummy word line DWL.

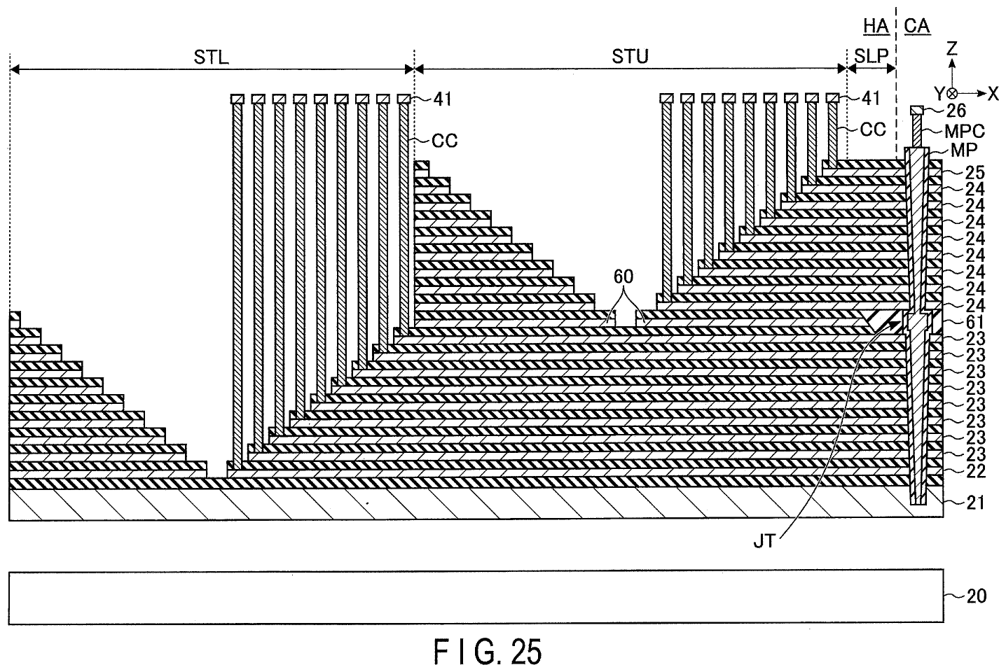

FIG. 25 shows an example of the cross-sectional structure of the memory cell array 10 in the hookup area HA according to the second embodiment. As shown in FIG. 25, the configuration of the memory cell array 10 in the hookup area HA according to the second embodiment differs from the configuration of the memory cell array according to the first embodiment described with reference to FIG. 7 in terms of the configuration of the stacked wirings above the joint portion JT. Specifically, the memory cell array 10 in the second embodiment includes a conductive layer 60 in the hookup area HA, and an insulating layer 61 in the cell area.

The conductive layer 60 corresponds to the dummy word line DWL. The conductive layer 60 is provided between uppermost one of the conductive layers 23 and the lowermost one of the conductive layers 24 in upper layer connection area STU, and is separated by an insulating layer between the uppermost one of the conductive layers 23 and the lowermost one of the conductive layers 24. The conductive layer 60 is disconnected in the sloping area SLP. The thickness of the conductive layer 60 is designed to be substantially equal to the thickness of each of the conductive layers 23 and 24. In addition, the thickness of each of the insulating layers sandwiching the conductive layer 60 is approximately equal to the thickness of the insulating layer between adjacent conductive layers 23 and is approximately equal to the thickness of the insulating layer between adjacent conductive layers 24.

The insulating layer 61 is provided between uppermost one of the conductive layers 23 and the lowermost one of the conductive layers 24 in cell area STU, and is in contact with, for example, the uppermost one of the conductive layers 23 and the lowermost one of the conductive layers 24. The insulating layer 61 is disconnected in the sloping area SLP and upper layer connection area STU, and the side surfaces of the disconnected insulating layer 61 are in contact with the side surface of the end of the conductive layer 60 and the end of the insulating layers sandwiching the conductive layer 60. The thickness of the insulating layer 61 is greater than the thickness of each of the insulating layers sandwiching the conductive layer 60, and is greater than the total thickness of the insulating layers sandwiching the conductive layer 60. In addition, the upper surface of the insulating layer 61 and the upper surface of the insulating layer on the conductive layer 60 are aligned. Therefore, in the memory cell array 10 in the second embodiment, the distance between the uppermost one of the conductive layers 23 and the lowermost one of the conductive layers 24 in the Z direction is substantially the same between the cell area CA and the upper layer connection area STU. In other words, in the second embodiment, the conductive layers 24 and 25 do not have a bent portion (inclined portion) in the sloping area SLP.

In the second embodiment, each of the conductive layers respectively corresponding to dummy word line DWL, word lines WL8 to WL15 and select gate line SGD has a terrace portion that does not overlap the upper conductive layers in upper layer connection area STU. The terrace portions in the upper layer connection area STU shown in FIG. 25 correspond to levels L11 to S20 shown in FIG. 24, respectively. Specifically, the terrace portion of the conductive layer 60 corresponds to level L11. The terrace portions of the eight conductive layers 24 correspond to levels L12 to L19, respectively. The terrace portion of the conductive layer 25 corresponds to level L20.

The other configurations of the semiconductor memory device 1 according to the second embodiment are similar to those of the semiconductor memory device 1 according to the first embodiment, and thus a description thereof will be omitted. In the semiconductor memory device 1 according to the second embodiment as well, the upper surface of the joint portion JT may be, or may not be in contact with the conductive layer 24. The conductive layer 60 provided between the uppermost one of the conductive layers 23 and the lowermost one of the conductive layers 24 is not limited to one, and a plurality of conductive layers 60 may be provided.

### [2-2] Manufacturing Method of Semiconductor Memory Device 1

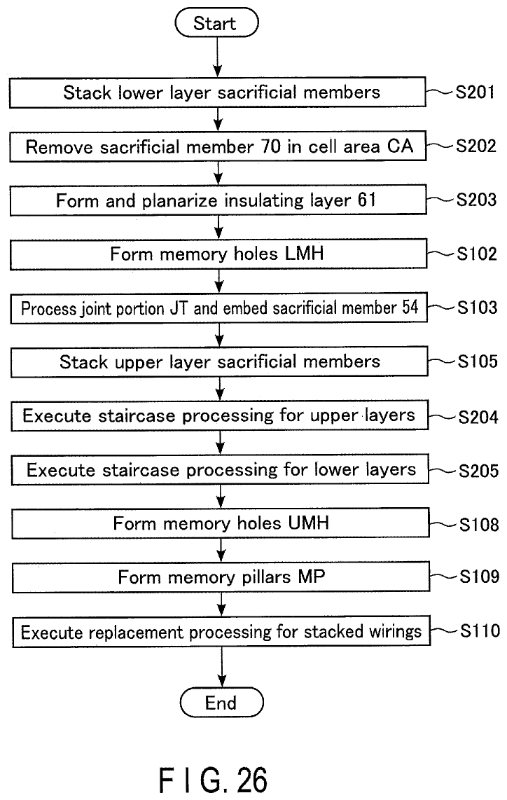

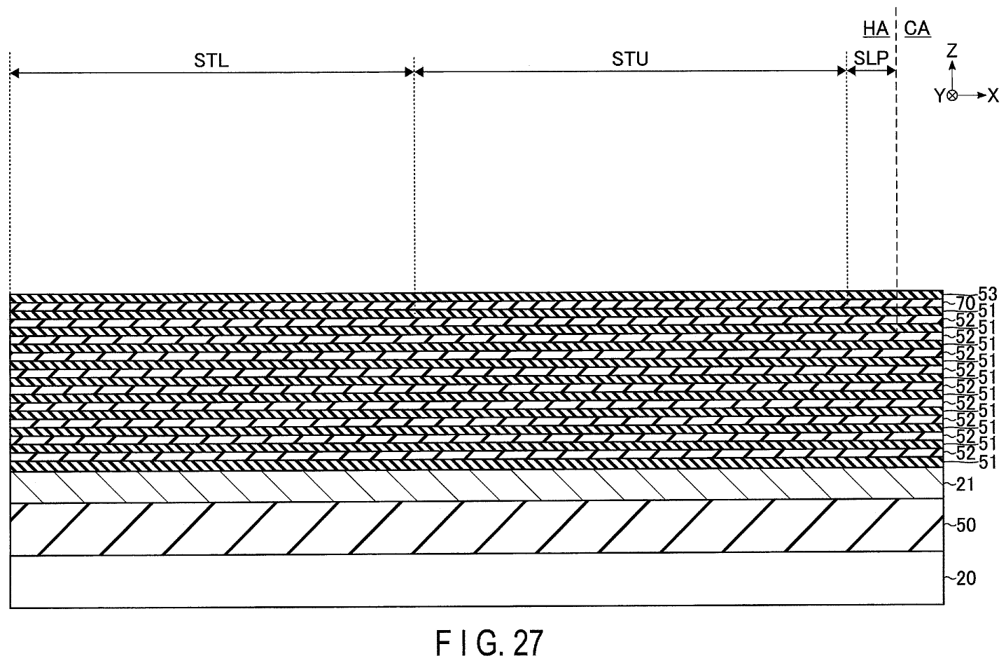

Hereinafter, with reference to FIG. 26 as appropriate, a description will be given of an example of a series of manufacturing steps in which a stacked structure corresponding to word line WL is formed in the semiconductor memory device 1 according to the second embodiment. FIG. 26 is a flowchart illustrating an example of a method of manufacturing the semiconductor memory device 1 according to the second embodiment. Each of FIGS. 27 to 36 shows an example of a cross sectional structure or a planar layout including a structure corresponding to the memory cell array 10 in the manufacturing process of the semiconductor memory device 1 according to the second embodiment.

First, as shown in FIG. 27, lower layer sacrificial members are stacked in the process of step S201. In the present process, first, as in step S101 of the first embodiment, the insulating layer 50 and the conductive layer 21 are sequentially stacked on the semiconductor substrate 20, and the insulating layers 51 and the sacrificial members 52 are alternately stacked on the conductive layer 21. Then, the insulating layer 51, the sacrificial member 70 and the insulating layer 53 are sequentially formed on the uppermost one of the sacrificial members 52. The sacrificial member 70 corresponds to the dummy word line DWL. The sacrificial member 70 is formed of a material similar to that of the sacrificial members 52 and contains, for example, silicon nitride (SiN).

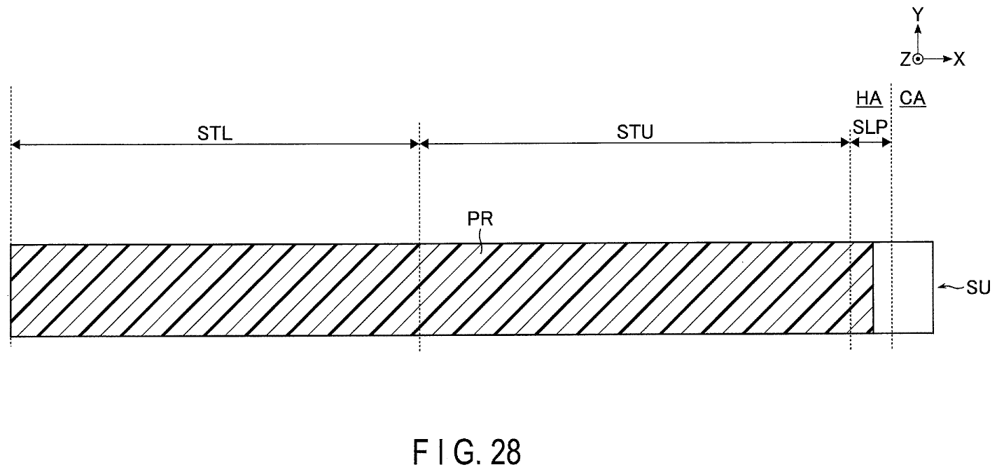

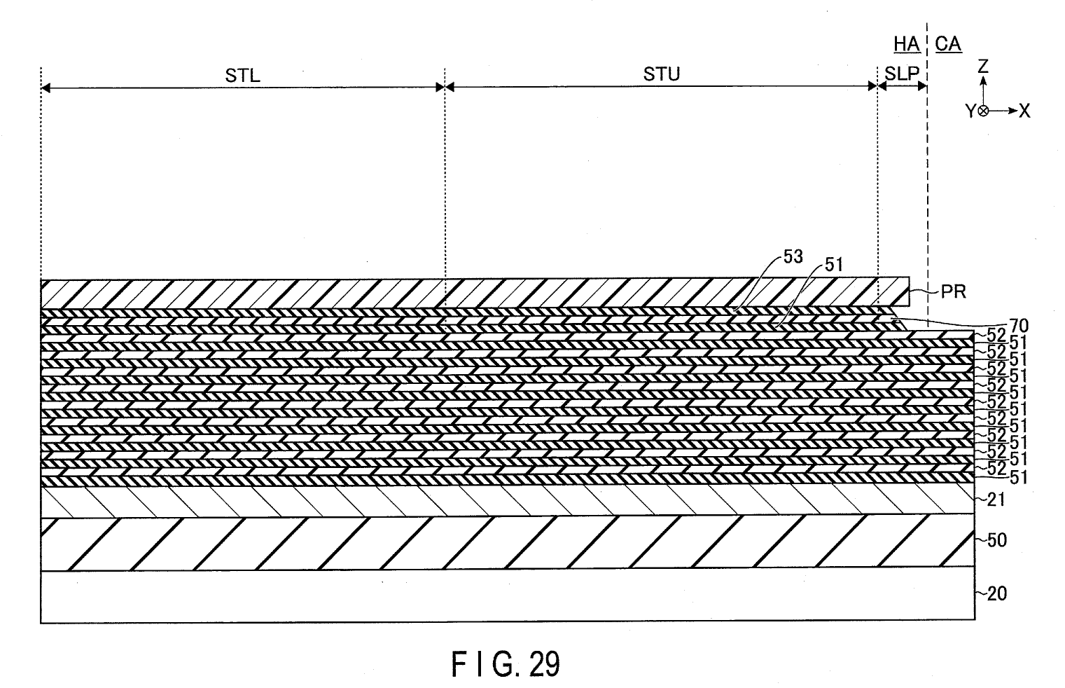

Next, as shown in. FIGS. 28 and 29, the sacrificial member 70 in the cell area CA is removed in the process of step S202. Specifically, a mask PR covering the lower layer connection area STL, the upper layer connection area STU and part of the sloping area SLP is first formed by photolithography or the like. The mask PR is, for example, a photoresist.

Then, etching is performed using the formed mask PR. Thereby, in the cell area CA, the insulating layers 51 and 53 and the sacrificial member 70 above the uppermost one of the sacrificial members 52 are removed. On the other hand, in the sloping area SLP, part of the insulating layer 53 beneath the end portion of the mask PR is removed as the etching progresses. The mask PR used in this process is removed after the processing of the insulating layers 51 and 53 and the sacrificial member 70 is completed. The etching in this process is performed in such a manner that at least sacrificial member 70 is removed from the cell area CA. Anisotropic etching may be used, or isotropic etching may be used in this process.

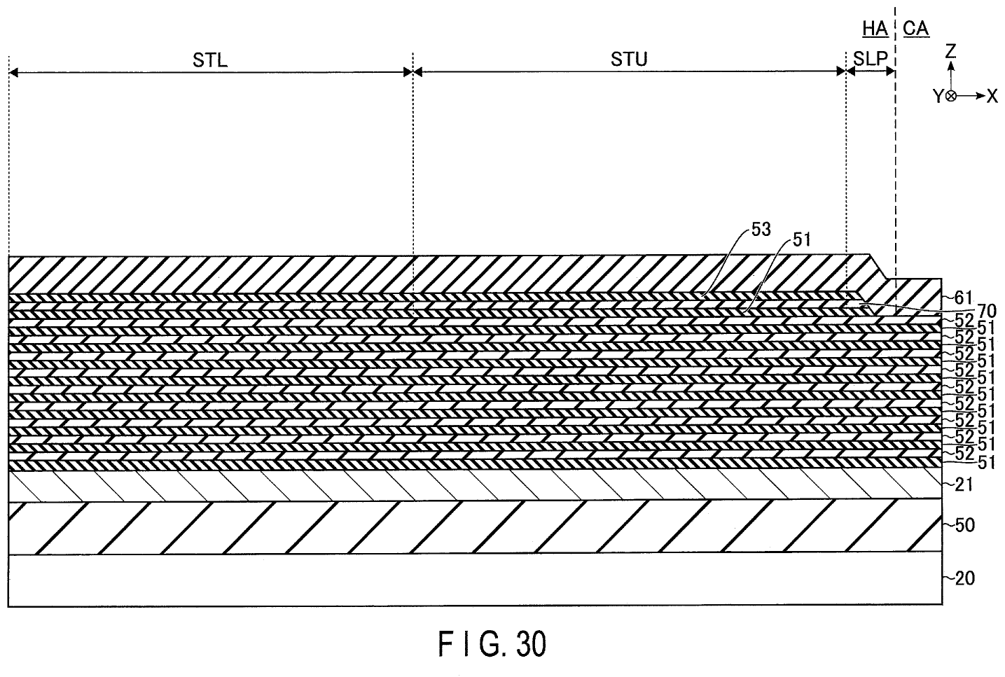

Next, the formation and planarization of insulating layer 61 are performed in the process of step S203. Specifically, first, as shown in FIG. 30, an insulating layer 61 is formed, and the region from which the sacrificial member 70 and the insulating layer 51 are removed in step S202 is filled with the insulating layer 61.

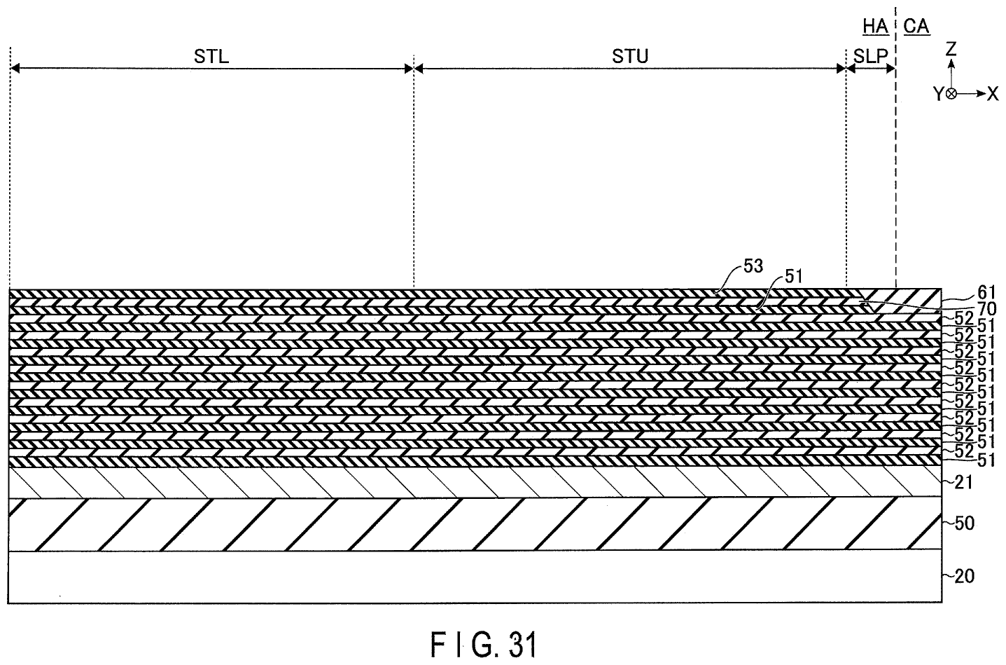

Then, the upper surface of the insulating layer 61 is made flat by, for example, CMP (Chemical Mechanical Polishing), and as shown in FIG. 31, the insulating layer 61 remains in the region where the sacrificial member 70 and the insulating layer 51 are removed in step S202. In the present process, it is preferable that the thickness of the insulating layer 53 be maintained to be substantially the same as the thickness of the insulating layer 51. In the second embodiment, the total thickness of the insulating layer 53 and the insulating layer 61 remaining on the insulating layer 53 may be substantially equal to the thickness of the insulating layer 51.

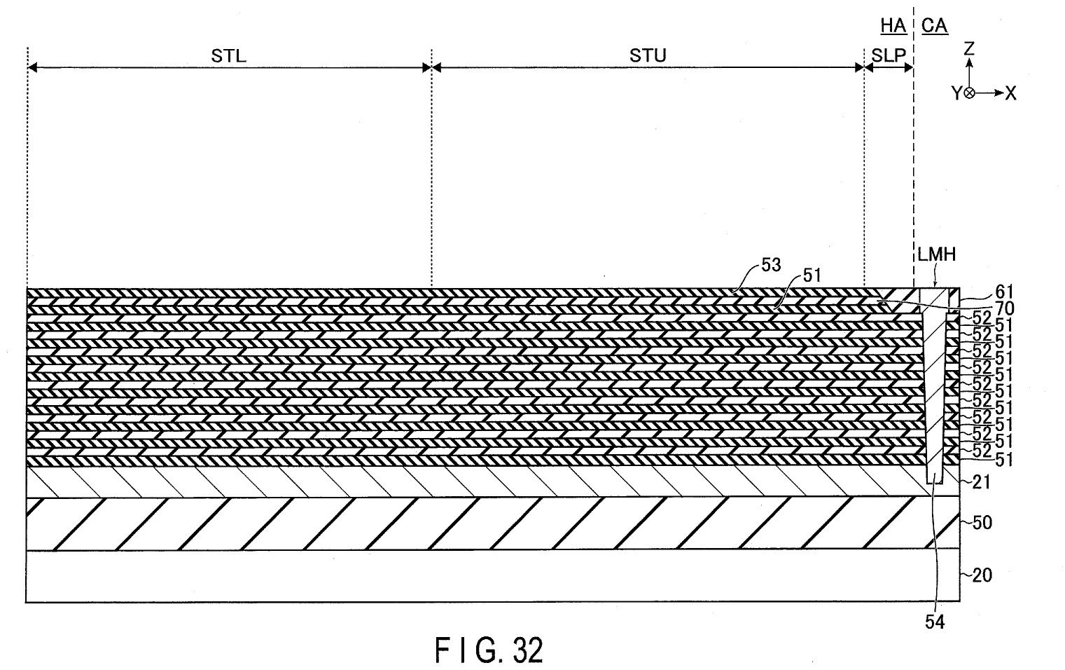

Next, the processes of steps S102 and S103 described in the first embodiment are performed. In short, as shown in FIG. 32, a memory hole LMH is formed, and the processing of the joint portion JT and the embedding of the sacrificial member 54 are performed. In the second embodiment, the memory hole LMH is provided to penetrate the insulating layer 61. The joint portion JT is processed such that, for example, the diameter of the portion where the memory hole LMH penetrates the insulating layer 61 is large.

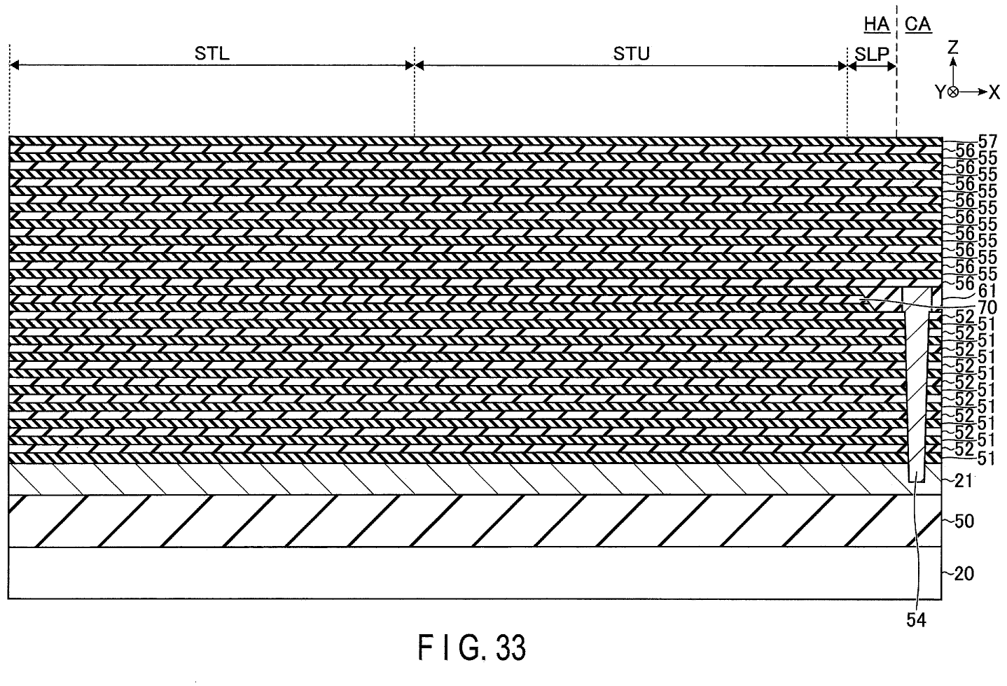

Then, the process of step S105 described in the first embodiment is performed. In short, as shown in FIG. 33, upper layer sacrificial members are stacked. In this process, a sacrificial members 56 and an insulating layer 55 are alternately stacked on the insulating layer 53 and the insulating layer 61, and the insulating layer 57 is formed on the uppermost one of the sacrificial members 56. In the second embodiment, the upper surface of insulating layer 53 and the upper surface of insulating layer 61 are aligned, so that an inclined structure such as that described in the first embodiment is not formed in the sloping area SLP.

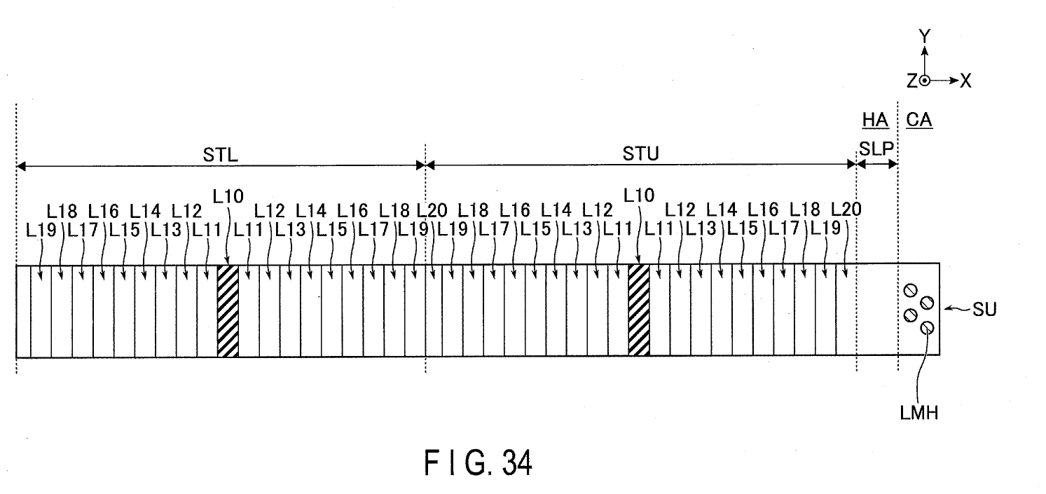

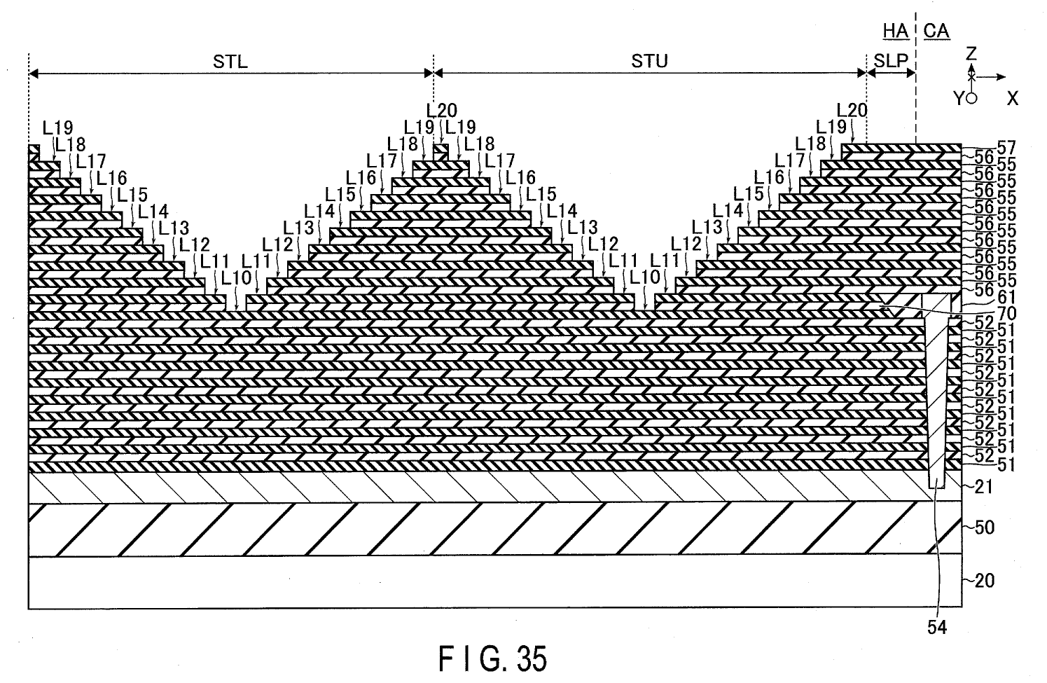

Next, staircase processing for the upper layers is executed in the process of step S204. The method of the staircase processing in step S204 is the same as step S106 described in the first embodiment, and a combination of slimming processing of the formed mask and anisotropic etching of the stacked structure is repeatedly performed until level L10 is formed. That is, the etching in the present process is performed until the sacrificial member 70 is divided. Thereby, as shown in FIG. 34 and FIG. 35, levels L10 to L20 are formed. More specifically, levels L11 to L20 are provided stepwise on both sides of level L10 in the X direction in each of lower layer connection area STL and upper layer connection area STU.

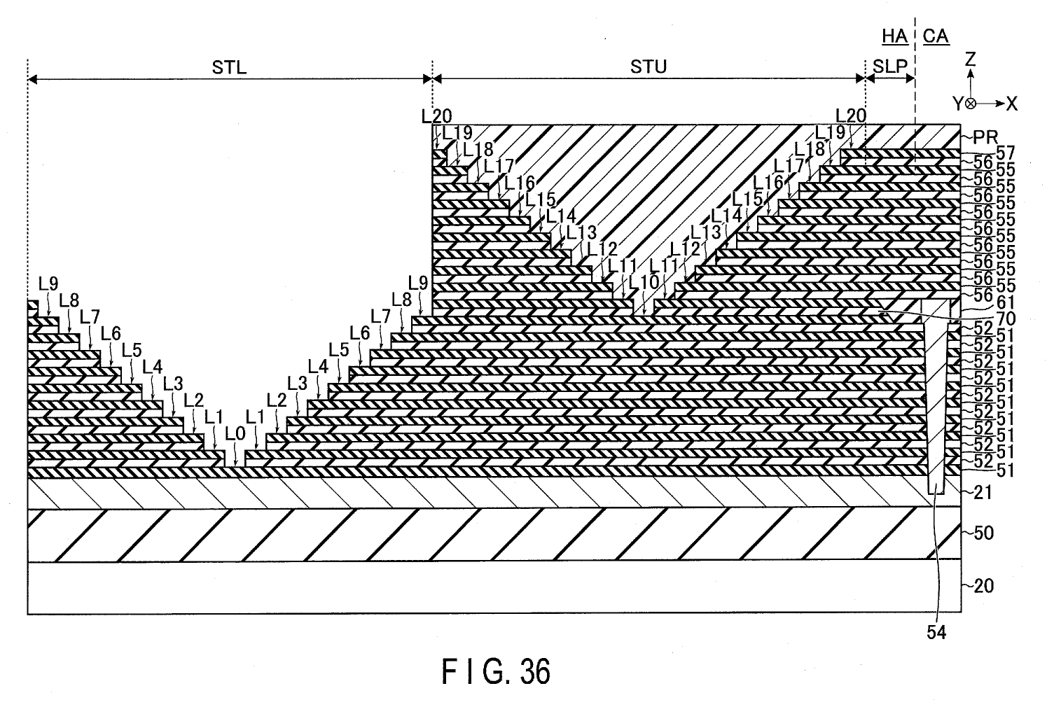

Next, as shown in FIG. 36, staircase processing for the lower layers is executed in the process of step S205.

The method of the staircase processing executed in step S205 is similar to that of step S107 described in the first embodiment, and a mask PR in which a region corresponding to the lower layer connection area STL is open is first formed. Anisotropic etching is performed until the part in which level L10 was formed before the processing reaches level L0. Thereby, levels L0 to L9 are formed. The mask PR used in the present process is removed after completion of the staircase processing of the lower layers.

Next, the processes of steps S108, S109 and S110 described in connection with the first embodiment are sequentially performed. Thus, memory pillar MP, source line SL connected to memory pillar MP, word line WL and select gate lines SGS and SGD are formed. Then, in the subsequent manufacturing process, a plurality of contacts CC respectively connected to word line WL and select gate lines SGS and SGD are formed using levels L1 to L9 and L2 to L20 formed in the above manufacturing process.

The other configurations of the semiconductor memory device 1 of the second embodiment described above are similar to those of the semiconductor memory device 1 according to the first embodiment, and thus a description thereof will be omitted. The manufacturing processes described above is merely an example, and other processes may be executed between the respective manufacturing processes, or the order in which to execute the manufacturing processes may be changed as long as no problem occurs.

### [2-3] Advantageous Effects of Second Embodiment

As described above, the semiconductor memory device 1 in the second embodiment has the dummy word line DWL (conductive layer 60) in the hookup area HA of the memory cell array 10. The insulating layer between the lowermost conductive layer 24 and the conductive layer 60 and the insulating layer between the uppermost one of the conductive layers 23 the conductive layer 60 are provided to have substantially the same thickness. That is, in the manufacturing process of the semiconductor memory device 1 according to the second embodiment, the thicknesses of the insulating layer and sacrificial member can be substantially uniform in the hookup area HA.

Therefore, in the manufacturing method of the semiconductor memory device 1 according to the second embodiment, etching property variations due to the influence of the layer between the uppermost one of the conductive layers 23 and the lowermost one of the conductive layers 24 can be suppressed in the case where a concave staircase structure is formed in each of the upper layer connection area STU and the lower layer connection area STL, and then the concave staircase structure of the lower layer connection area STL is collectively processed to the lowermost layer, as in steps S204 and S205.

As a result, in the method of manufacturing the semiconductor memory device 1 according to the second embodiment, defects in the contacts CC due to characteristic variations in the staircase structure of the lower layer connection area STL can be suppressed. That is, the semiconductor memory device 1 according to the second embodiment can suppress defects which may be caused by the contacts CC, and the manufacturing yield can be improved, as in the first embodiment.

### [3] Third Embodiment

The semiconductor memory device 1 according to the third embodiment differs from the semiconductor memory device 1 of the second embodiment in that the staircase structure in the hookup area HA is omitted and stacked wirings and the row decoder module 15 are electrically connected to each other by contacts penetrating the stacked wirings. A description will be given of the points in which the semiconductor memory device 1 according to the third embodiment differs from those of the first and second embodiments.

### [3-1] Configuration of Memory Cell Array 10

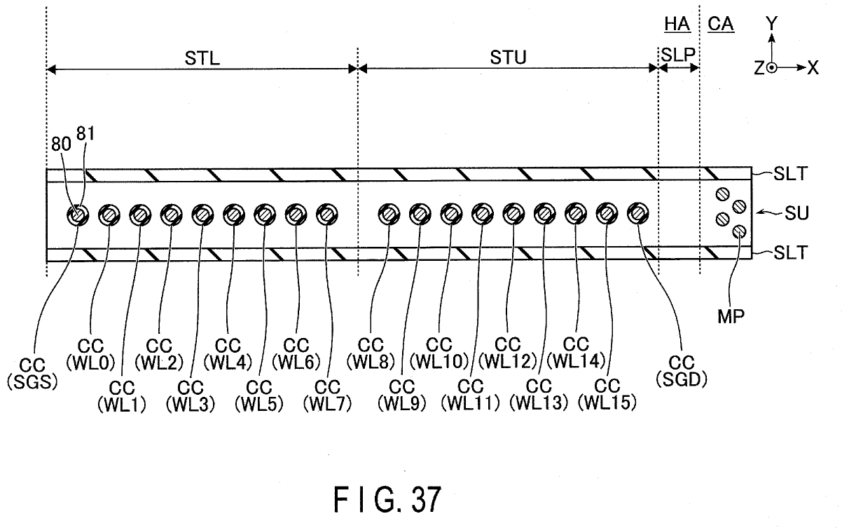

FIG. 37 shows an example of a planar layout of the memory cell array 10 in the hookup area HA according to the third embodiment. As shown in FIG. 37, the planar layout of the memory cell array 10 in the hookup area HA according to the third embodiment differs from the planar layout of the memory cell array 10 described with reference to FIG. 24 in the second embodiment, in terms of the number of levels provided, that is, levels L0 to L20 are omitted. In addition, each of contacts CC in the third embodiment includes a conductor portion 80 and an insulating film 81.

Specifically, contacts CC in the third embodiment penetrate the stacked wirings such as the word lines WL. The bottoms of the contacts CC respectively corresponding to select gate line SGS, word lines WL0 to WL15 and select gate line SGD are in contact with the corresponding interconnect layers. In each of the contacts CC, the conductor portion 80 is provided in a columnar shape extending in the Z direction. The insulating film 81 is provided to cover the side surface of the conductor portion 80, and electrically insulates the contact CC from the stacked wirings which the contact CC penetrates.

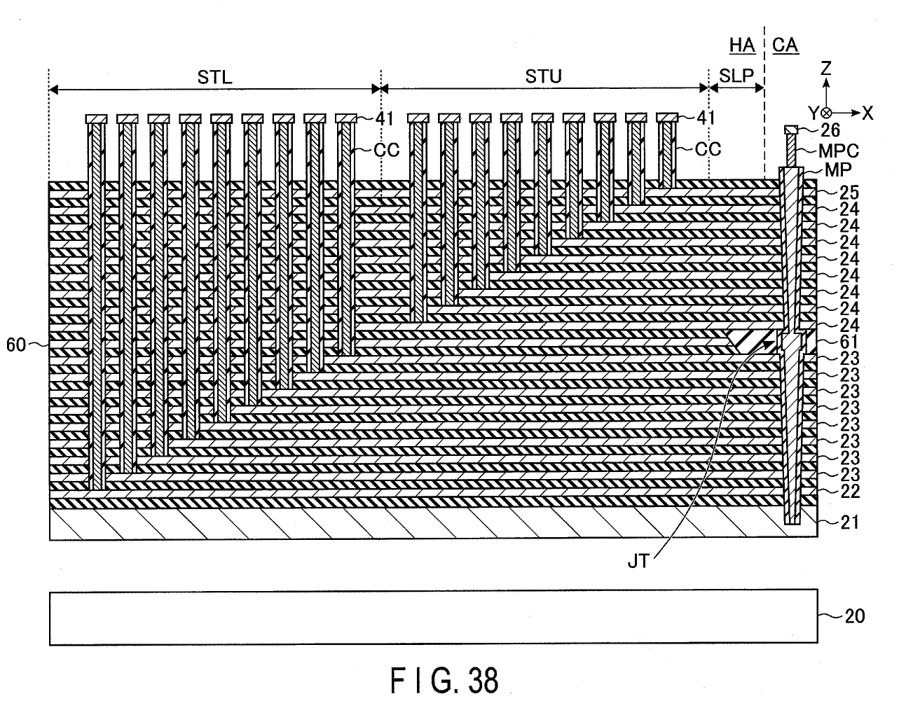

FIG. 38 shows an example of the cross-sectional structure of the memory cell array 10 in the hookup area HA according to the third embodiment. As shown in FIG. 38, the configuration of the memory cell array 10 in the hookup area HA according to the third embodiment differs from the configuration of the memory cell array according to the second embodiment described with reference to FIG. 25 in terms of the configuration of the stacked wirings and contacts CC.

Specifically, in the hookup area HA, the end portions of the conductive layers 22, 23, 24 and 25 are provided from the cell area CA to the lower layer connection area STL. In lower layer connection area STL and upper layer connection area STU, the conductive layer 60 is provided between the uppermost one of the conductive layers 23 and the lowermost one of the conductive layers 24. Each contact CC penetrates the conductive layers that are upper than the corresponding conductive layer.

For example, the contact CC corresponding to select gate line SGS penetrates the conductive layers 23, 24, 25 and 60 which are above the conductive layer 22, and the bottom thereof is in contact with the conductive layer 22. The contact CC corresponding to the word line WL0 penetrates the conductive layers 23, 24, 25 and 60 which are above the lowermost conductive layer 23, and the bottom thereof is in contact with the lowermost conductive layer 23. The contact CC corresponding to the word line WL8 penetrates the conductive layers 24 and 25 which are above the lowermost one of the conductive layers 24, and the bottom thereof is in contact with the lowermost one of the conductive layers 24. The same holds true of the other contacts CC, and the contacts CC penetrate the upper conductive layers in accordance with the interconnect layer to be connected, and the bottoms of the contacts CC are in contact with the respective conductive layers.

The other configurations of the semiconductor memory device 1 according to the third embodiment are similar to those of the semiconductor memory device 1 of the second embodiment, and thus a description thereof will be omitted. In the semiconductor memory device 1 according to the third embodiment as well, the upper surface of the joint portion JT may be, or may not be in contact with the conductive layer 24. Conductive layer 60 provided between the uppermost one of the conductive layers 23 and the lowermost one of the conductive layers 24 is not limited to one, and a plurality of conductive layers 60 may be provided. The contact configuration employed in the semiconductor memory device 1 according to the third embodiment is applicable to the stacked wirings in the hookup area HA corresponding to the semiconductor memory device 1 according to the first embodiment.

### [3-2] Manufacturing Method of Semiconductor Memory Device 1

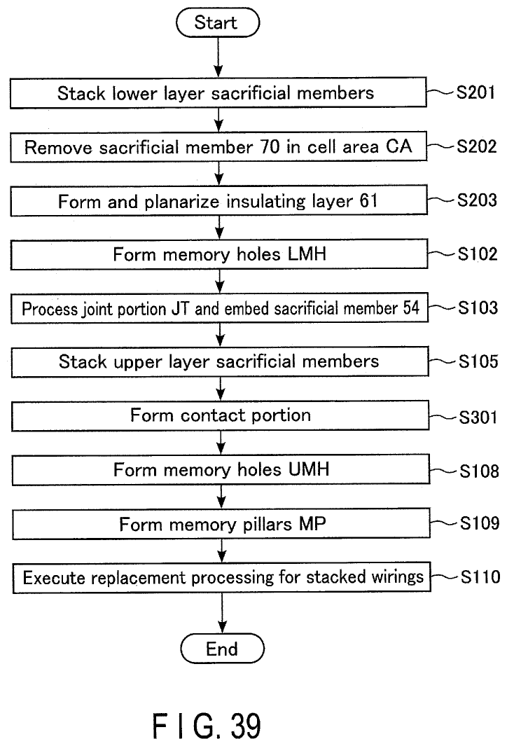

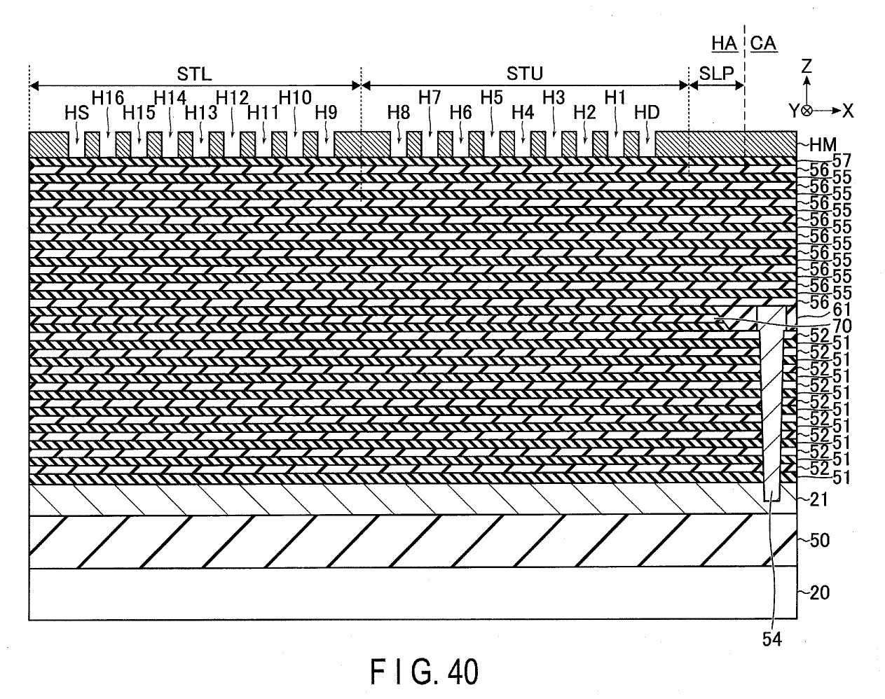

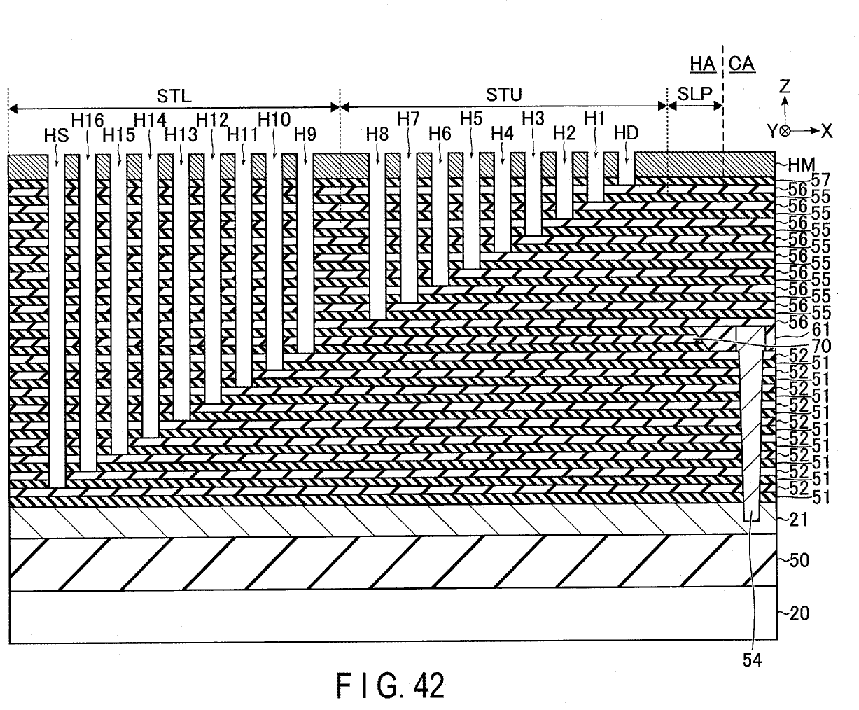

Hereinafter, with reference to FIG. 39 as appropriate, a description will be given of an example of a series of manufacturing steps in which a stacked structure corresponding to the word line WL is formed in the semiconductor memory device 1 according to the third embodiment. FIG. 39 is a flowchart illustrating an example of a method of manufacturing the semiconductor memory device 1 according to the third embodiment. Each of FIGS. 40 and 42 shows an example of a cross sectional structure including a structure corresponding to the memory cell array 10 in the manufacturing process of the semiconductor memory device 1 according to the third embodiment.

First, as in the second embodiment, the processes of steps S201, S202, S203, S102, S103 and S105 are sequentially performed. Thereby, a structure similar to that of FIG. 33 described in the second embodiment is formed on the semiconductor substrate 20.

Next, a contact portion is formed in the process of step S301. Specifically, a hard mask HM is first formed as shown in FIG. 40. To form the hard mask HM, for example, a metal film is formed on the insulating layer 57. Then, the metal film is processed by photolithography and etching such that regions where a plurality of contacts CC respectively corresponding to the select gate lines SGS and SGD and the word lines WL0 to WL15 are to be formed are opened. Hereinafter, the opening of the hard mask HM corresponding to the select gate line SGS will be referred to as opening HS. The openings of the hard mask HM corresponding to the word lines WL15 to WL0 will be referred to as openings H1 to H16, respectively. The opening of the hard mask HM corresponding to the select gate line SGD will be referred to as opening HD.

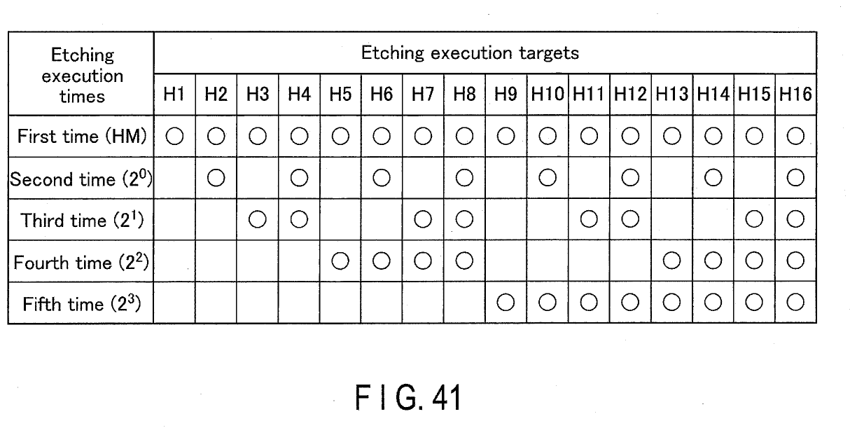

An example of a method for forming a plurality of contact holes that reach conductive layers respectively corresponding to openings H1 to H16 will be described with reference to FIG. 41. FIG. 41 is a table showing an example of a method in which contact holes are processed in the manufacturing process of the semiconductor memory device 1 according to the third embodiment. FIG. 41 shows the relationship between the number of times etching is executed and openings which are to be etched when the etching is performed. “◯” indicates that etching is executed at the time of processing. The openings for which “◯” is not shown are openings that are covered with a photoresist or the like at the time of processing and therefore etching is not executed.

As shown in FIG. 41, in the first-time processing, etching is performed for openings H1 to H16, and contact holes reaching, for example, the uppermost contact layer via a hard mask HM are formed. In the present specification, the “contact layer” corresponds to a target conductive layer which the contact hole is made to reach.

In the second-time processing, openings H2, H4, H6, H8, H10, H12, H14 and H16 are etching targets, one set (2°) of a sacrificial member and an insulating layer are etched, and a plurality of contact holes reaching two different layers are formed.

In the third-time processing, openings H3, H4, H7, H8, H11, H12, H15 and H16 are etching targets, two sets (2¹) of a sacrificial member and an insulating layer are etched, and a plurality of contact holes reaching four different layers are formed.

In the fourth-time processing, openings H5, H6, H7, H8, H13, H14, H15 and H16 are etching targets, four sets (2²) of a sacrificial member and an insulating layer are etched, and a plurality of contact holes reaching eight different layers are formed.

In the fifth-time processing, openings H9, H10, H11, H12, H13, H14, H15 and H16 are etching targets, eight sets (2³) and one set of a sacrificial member and an insulating layer are etched, and a plurality of contact holes reaching 16 different layers are formed.

As described above, after the contact holes reaching the uppermost contact layer are opened by the first-time processing, the 2^{k-1} sets of a sacrificial member and an insulating layer are etched in the k-th processing after the first-time processing (k is an integer of 1 or more). In this manner, a plurality of contact holes respectively reaching different 2^{k} layers are formed.

An example of the cross-sectional structure of the memory cell array 10 in which contact holes are formed in the method described with reference to FIG. 41 corresponds to FIG. 42. As shown in FIG. 42, the bottoms of the contact holes corresponding to openings HD and HD1 to HD8 respectively reach the sacrificial members 56 of different layers. The bottoms of the contact holes respectively corresponding to the openings HD9 to HD16 and HS reach the sacrificial members 52 of different layers. When the processing of the contact holes is completed, the hard mask HM is removed. Then, a sacrificial member different from sacrificial members 52 and 56 is embedded in the contact holes formed by the present process.

Next, the processes of steps S108, S109 and S110 described in the first embodiment are sequentially performed. Thus, memory pillar MP, source line SL connected to memory pillar MP, word line WL and select gate lines SGS and SGD are formed. Then, a plurality of contacts CC respectively connected to word lines WL and select gate lines SGS and SGD are formed, using the contact holes formed in the above manufacturing process.

The other configurations of the semiconductor memory device 1 according to the third embodiment described above are similar to those of the semiconductor memory device 1 according to the first embodiment, and thus a description thereof will be omitted. The manufacturing processes described above is merely an example, and other processes may be executed between the respective manufacturing processes, or the order in which to execute the manufacturing processes may be changed as long as no problem occurs. The contacts CC may be formed after the formation of the contact holes and before the formation of the memory pillar MP.

### [3-3] Advantageous Effects of Third Embodiment

As described above, the semiconductor memory device 1 according to the third embodiment has the dummy word line DWL (conductive layer 60) in the hookup area HA of the memory cell array 10, as in the second embodiment. In the memory cell array 10 in the third embodiment, contacts CC penetrating the stacked wirings are provided without forming the staircase contact region.

Therefore, in the manufacturing method of the semiconductor memory device 1 according to the third embodiment, etching property variations due to the influence of the layer between the uppermost one of the conductive layers 23 and the lowermost one of the conductive layers 24 can be suppressed in the processing in which contact holes corresponding to the stacked wirings of the upper layer connection area STU and contact holes corresponding to the stacked wirings of the lower layer connection area STL are formed.

As a result, in the method of manufacturing the semiconductor memory device 1 according to the third embodiment, defects in the contacts CC due to variation in the contact hole depth in the lower layer connection area STL can be suppressed. That is, the semiconductor memory device 1 according to the third embodiment can suppress defects which may be caused by the contacts CC, and the manufacturing yield can be improved, as in the second embodiment.

### [4] Fourth Embodiment

The semiconductor memory device 1 according to the fourth embodiment is a modification of the staircase structure in the hookup area HA, which corresponds to the semiconductor memory device 1 according to the first embodiment. A description will be given of the points in which the semiconductor memory device 1 according to the fourth embodiment differs from those of the first to third embodiments.

### [4-1] Configuration of Memory Cell Array 10

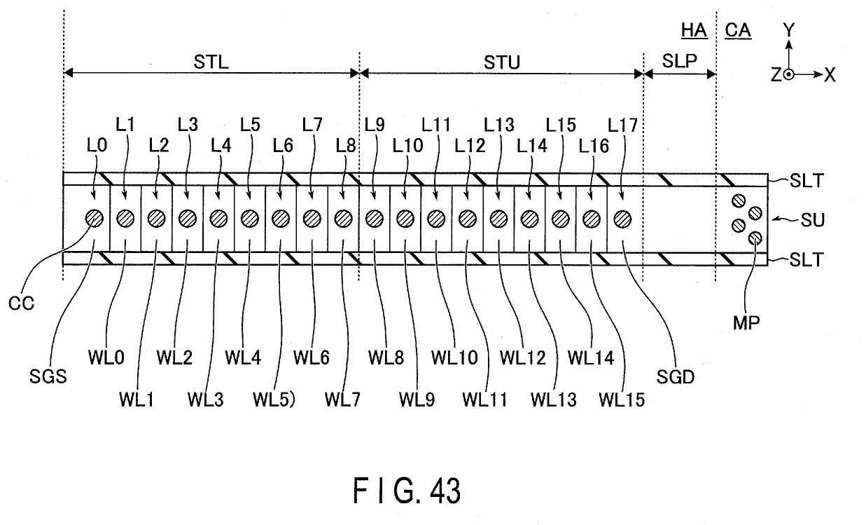

FIG. 43 shows an example of a planar layout of the memory cell array 10 in the hookup area HA according to the fourth embodiment. As shown in FIG. 43, the planar layout of the memory cell array 10 in the hookup area HA in the fourth embodiment differs from the planar layout of the memory cell array 10 described with reference to FIG. 6 in connection with the first embodiment, in that the staircase structure of the lower layer connection area STL and the staircase structure of the upper layer connection area STU are continuous.

Specifically, in the fourth embodiment, the lower layer connection area STL includes levels L0 to L8, and the upper layer connection area STU includes levels L9 to L17. In the hookup area HA, levels L0 to L17 are arranged in the X direction. Level L0 corresponds to the select gate line SGS. Levels L1 to L16 correspond to the word lines WL0 to WL15, respectively. Level L17 corresponds to the select gate line SGD.

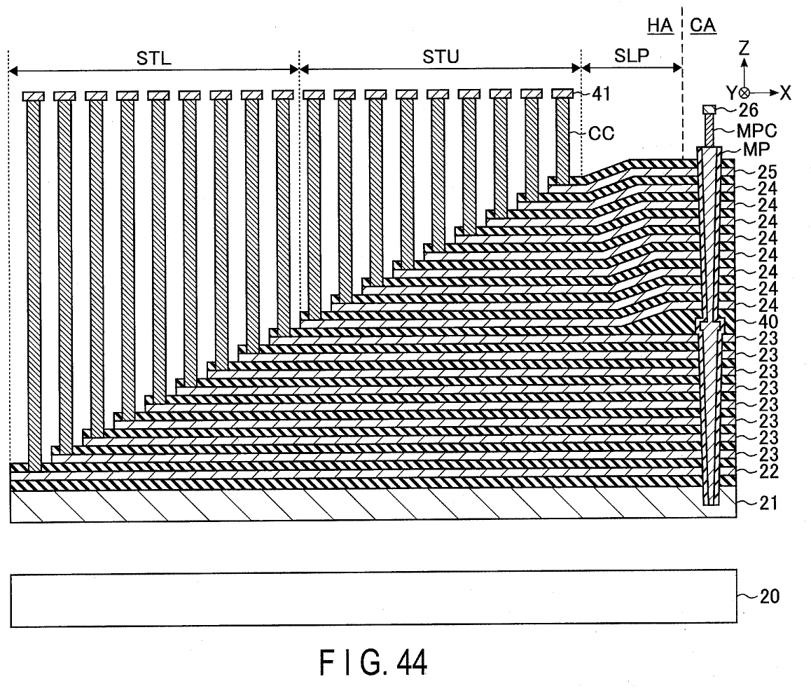

FIG. 44 shows an example of the cross-sectional structure of the memory cell array 10 in the hookup area HA according to the fourth embodiment. As shown in FIG. 44, the configuration of the memory cell array 10 in the hookup area HA according to the fourth embodiment differs from the configuration of the memory cell array 10 in the first embodiment described with reference to FIG. 7 in that a staircase portion to which contacts CC are not connected is not provided. In other words, in the memory cell array 10 in the fourth embodiment, the staircase structure formed as being concave in the X direction is not provided in the lower layer connection area STL or upper layer connection area STU described in the first embodiment.

Therefore, in the memory cell array 10 in the fourth embodiment, the terrace portion of the uppermost one of the conductive layers 23 in the lower layer connection area STL and the terrace portion of the lowermost one of the conductive layers 24 in the upper layer connection area STU are adjacent to each other. The other configurations of the semiconductor memory device 1 according to the fourth embodiment are similar to those of the semiconductor memory device 1 in the first embodiment, and thus a description thereof will be omitted.

### [4-2] Manufacturing Method of Semiconductor Memory Device 1

The flow of the method of manufacturing the semiconductor memory device 1 according to the fourth embodiment is similar to that of the semiconductor memory device 1 according to the first embodiment. In the fourth embodiment, however, the process of step S106 (i.e., processing for the upper layer staircase structure) and the process of step S107 (i.e., processing for the lower layer staircase structure) of the method of manufacturing the semiconductor memory device according to the first embodiment are successively performed, and the processing method is different.

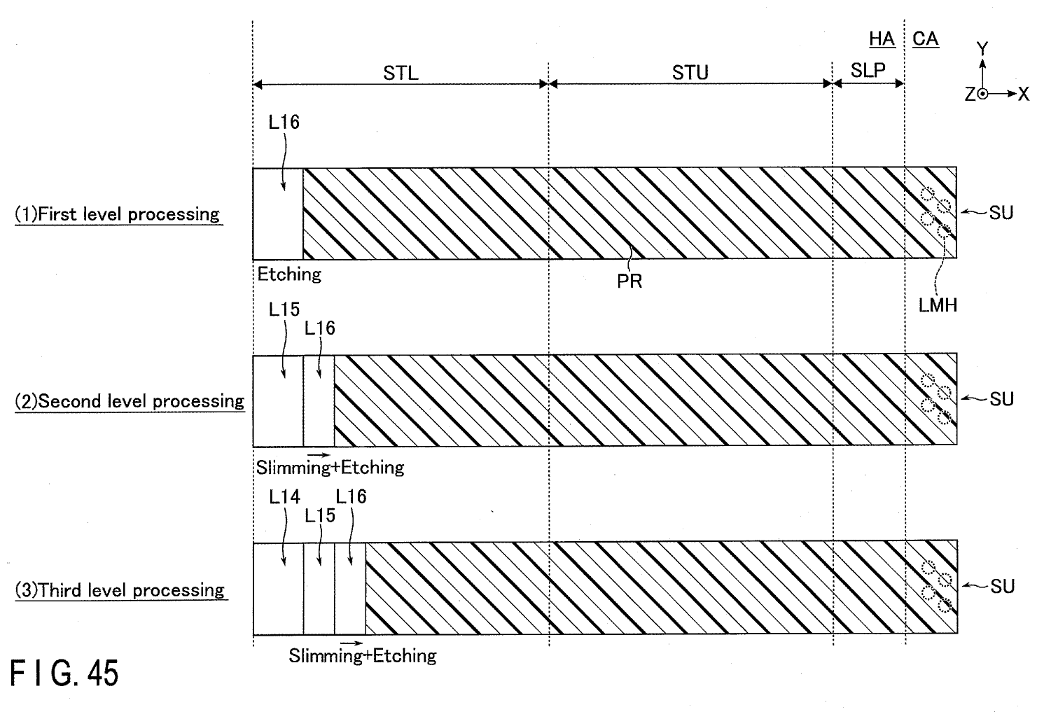

Hereinafter, a method for the staircase processing of the semiconductor memory device 1 in the hookup area. HA according to the fourth embodiment will be described with reference to FIGS. 45 to 47. Each of FIGS. 45 to 47 shows an example of a cross sectional structure or a planar layout including a structure corresponding to the memory cell array 10 in the manufacturing process of the semiconductor memory device 1 according to the fourth embodiment.

First, as shown in FIG. 45, a mask PR is formed by photolithography or the like, in which a region corresponding to level L0 shown in FIG. 43 is open. Then, the insulating layer 57 and the sacrificial member 56 are processed by one level by anisotropic etching, and level L16 is formed in the opening portion of the mask PR as shown in FIG. 45(1) (first level processing).

Then, the slimming process is performed for the mask PR such that the region corresponding to levels L1 shown in FIG. 43 is exposed. Subsequently, the insulating layer 55 or 57 and the sacrificial member 56 are processed by one level by anisotropic etching to form levels L15 and L16 in the opening portion of the mask PR as shown in FIG. 45(2) (second level processing).

Then, the slimming process is performed for the mask PR such that the region corresponding to level L2 shown in FIG. 43 is exposed. Subsequently, the insulating layer 55 or 57 and the sacrificial member 56 are processed by one level by anisotropic etching, and levels L14, L15 and L16 are formed in the opening portion of the mask PR as shown in FIG. 45(3) (third level processing).

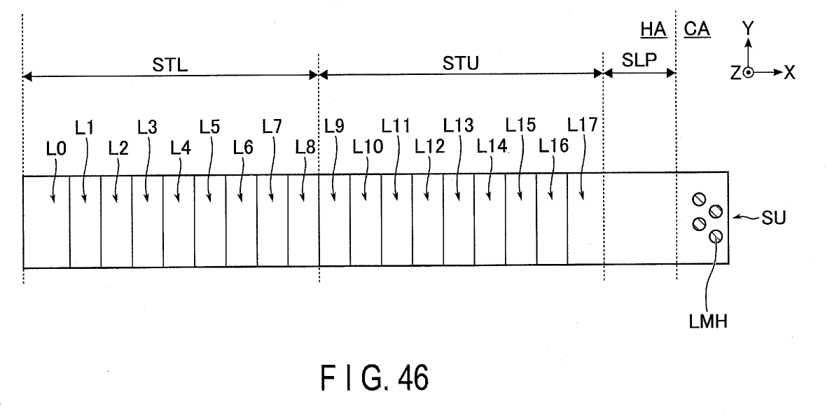

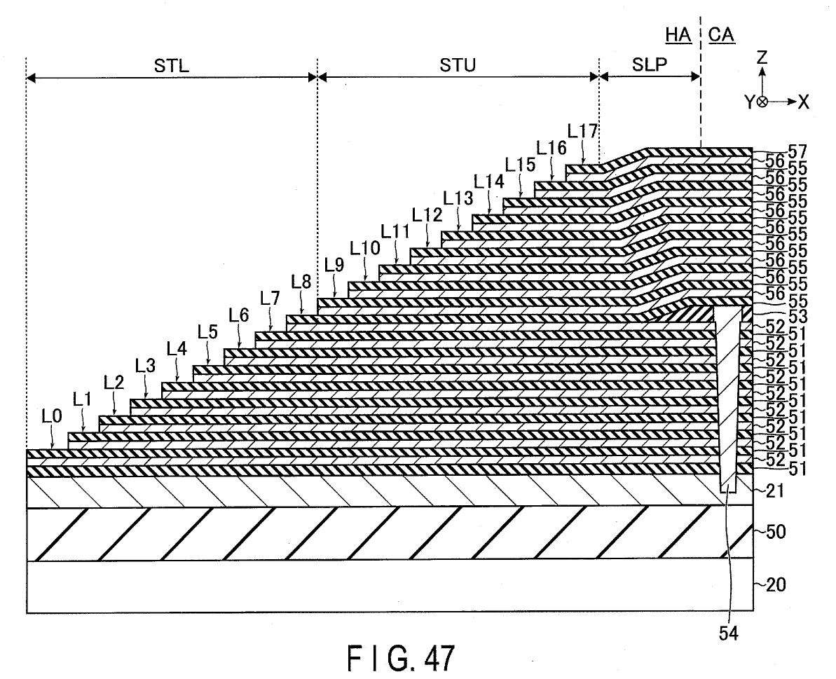

Likewise, the combination of the slimming process of the mask PR and the anisotropic etching of the stacked structure is repeatedly performed until level L0 is formed. The mask PR used in the present process is removed after completion of the staircase processing. Thereby, as shown in FIG. 46 and FIG. 47, levels L0 to L17 are formed. More specifically, levels L0 to L8 in the lower layer connection area STL and levels L9 to L17 in the upper layer connection area STU are sequentially provided in the X direction. The other processes of manufacturing the semiconductor memory device 1 according to the fourth embodiment are similar to those of the semiconductor memory device 1 according to the first embodiment, and thus a description thereof will be omitted.

### [4-3] Advantageous Effects of Fourth Embodiment

As described above, in the semiconductor memory device 1 according to the fourth embodiment, a staircase structure different from that described in the first embodiment is formed in the hookup area HA. Similarly to the first embodiment, the configuration of the memory cell array 10 in the hookup area HA as provided in the semiconductor memory device 1 according to the fourth embodiment can suppress characteristic variations in the staircase structure which are due to the influence of insulating layer 40 between the uppermost one of the conductive layers 23 and the lowermost one of the conductive layers 24. Therefore, the semiconductor memory device 1 according to the fourth embodiment can suppress defects which may be caused by the contacts CC, and the manufacturing yield can be improved, as in the first embodiment.

### [4-4] Modification of Fourth Embodiment

The staircase structure in the hookup area HA of the semiconductor memory device 1 according to the fourth embodiment described above can also be applied to the semiconductor memory device 1 according to the second embodiment. An example of a combination of the second embodiment and the fourth embodiment will be described as a modification of the fourth embodiment.

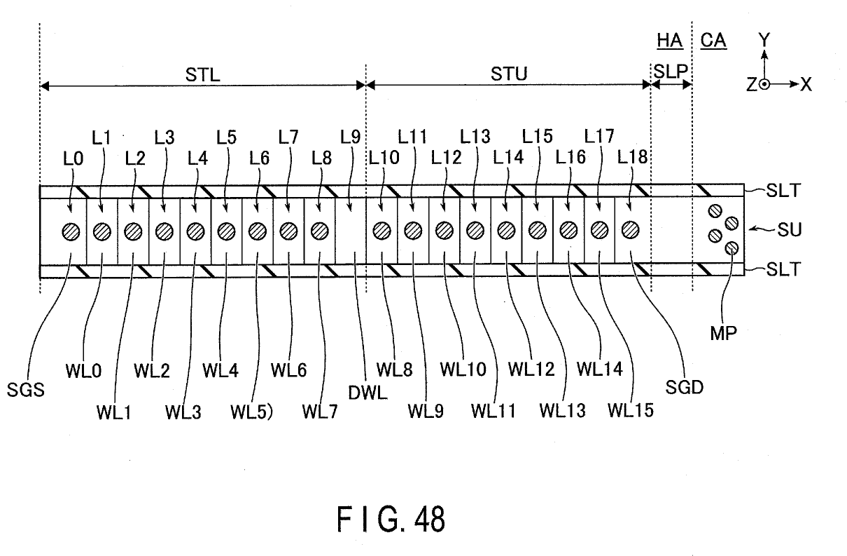

FIG. 48 shows an example of a planar layout of the memory cell array 10 in the hookup area HA according to a modification of the fourth embodiment. As shown in FIG. 48, the planar layout of the memory cell array 10 in the hookup area HA according to the modification of the fourth embodiment differs from the planar layout of the memory cell array 10 described with reference to FIG. 24 in the second embodiment, in that the staircase structure of the lower layer connection area STL and the staircase structure of the upper layer connection area STU are continuous.

Specifically, in the modification of the fourth embodiment, the lower layer connection area STL includes levels L0 to L9, and the upper layer connection area STU includes levels L10 to L18. In the hookup area HA, levels L0 to L18 are arranged in the X direction. Level L0 corresponds to the select gate line SGS. Levels L1 to L8 correspond to the word lines WL0 to WL7, respectively. Level L9 corresponds to the dummy word line DWL. Levels L10 to L17 correspond to the word lines WL8 to WL15, respectively. Level L18 corresponds to the select gate line SGD. Although level L9 is included in the lower layer connection area STL in the present modification, level L9 may be included in the upper layer connection area STU.

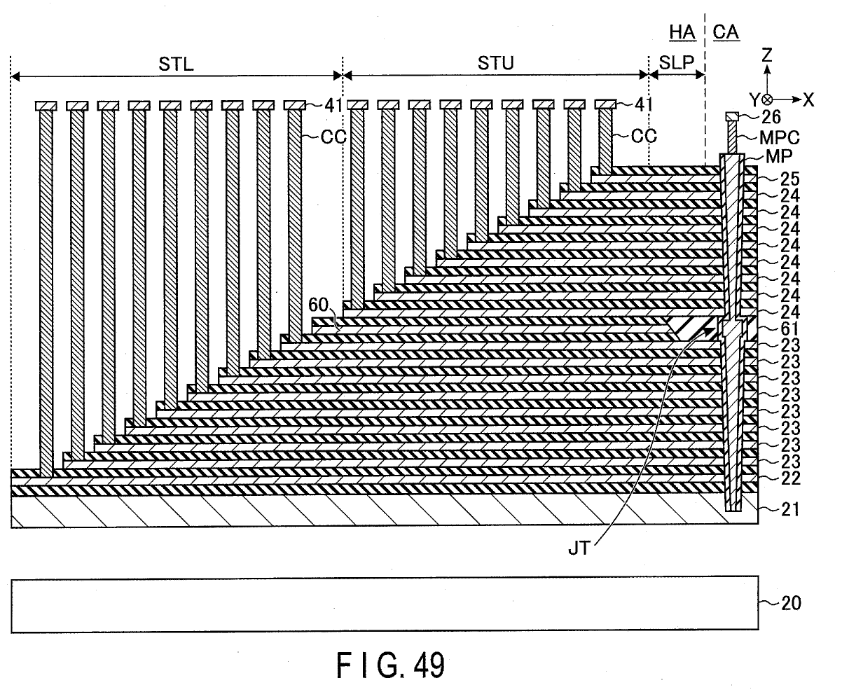

FIG. 49 shows an example of the cross-sectional structure of the memory cell array 10 in the hookup area HA according to the modification of the fourth embodiment. As shown in FIG. 49, the configuration of the memory cell array 10 in the hookup area HA according to the modification of the fourth embodiment differs from the configuration of the memory cell array 10 according to the second embodiment described with reference to FIG. 25 in that a staircase portion to which contacts CC are not connected is not provided. In other words, in the memory cell array 10 according to the modification of the fourth embodiment, a staircase structure formed as being concave in the X direction, such as the staircase structure described in the second embodiment, is not provided in the lower layer connection area STL or upper layer connection area STU.

Therefore, in the memory cell array 10 according to the modification of the fourth embodiment, the terrace portion of the uppermost one of the conductive layers 23 in the lower layer connection area STL and the terrace portion of the lowermost one of the conductive layers 24 in the upper layer connection are STU are adjacent to each other, with the terrace portion corresponding to the dummy word line DWL being interposed.

The other configurations of the semiconductor memory device 1 according to the modification of the fourth embodiment are similar to those of the semiconductor memory device 1 according to the second embodiment. The method of manufacturing the semiconductor memory device 1 according to the modification of the fourth embodiment is the same as a combination of the manufacturing method described in the second embodiment with the manufacturing method described in the fourth embodiment, and a description of that method will be omitted. The semiconductor memory device 1 according to the modification of the fourth embodiment can achieve the same advantageous effects as the semiconductor memory device 1 according to the fourth embodiment.

[5] Other Modifications

A semiconductor memory device according to an embodiment includes, a stacked portion, a pillar, a plurality of first contacts, and a plurality of second contacts. The stacked portion is provided in a first region including a memory cell and in a second region different from the first region. The stacked portion includes a plurality of first conductive layers, a plurality of second conductive layers and a first insulating layer. The first conductive layers are stacked in a first direction above a substrate. The first conductive layers are separated from each other. The second conductive layers are stacked in the first direction above the first conductive layers. The second conductive layers are separated from each other. The first insulating layer is provided between an uppermost one of the first conductive layers and a lowermost one of the second conductive layers. The pillar penetrates the first conductive layers, the second conductive layers and the first insulating layer in the first region. The first contacts are respectively connected to the first conductive layers in the second region. The second contacts are respectively connected to the second conductive layers in the second region. A thickness of the first insulating layer is greater in the first region than in the second region in the first direction. With this configuration, the manufacturing yield of the semiconductor memory device can be improved.

In the above embodiments, the memory pillar MP and the conductive layer 26 may be electrically connected via two or more contacts, or may be electrically connected via other wirings. Each slit SLT may contain a plurality of types of insulators. The number of memory pillars MP and the arrangement thereof may be designed to be any number and arrangement. The number of bit lines BL overlapping each memory pillar MP can be designed to be any number. Where memory pillars MP are arranged at high density, one or more slits that divide only conductive layer 25 may be provided between the adjacent slits SLT. In this case, the area partitioned by a slit that divides conductive layer 25 and slit SLT corresponds to one string unit SU.

In connection with the above embodiments, reference was made to the case where the staircase structure along the X direction is formed in the hookup area HA, but the memory cell array 10 may have staircase structures arranged in two or more rows. Specifically, where staircase structures arranged, for example, in two rows are formed, the terrace portion of the conductive layer corresponding to the word line WL0 is adjacent to the terrace portion of the conductive layer corresponding to the word line WL1 in the Y direction, and is also adjacent to the terrace portion of the conductive layer corresponding to the word line WL2 in the X direction.

In connection with the first and second embodiments, reference was made to an example in which a staircase structure having a concave shape in the X direction is formed in each of the lower layer connection area STL and the upper layer connection area STU, but this is not restrictive. For example, two or more concave staircase structures may be provided in each of the lower layer connection area STL and the upper layer connection area STU. In this case, in the hookup area HA, three or more concave staircase structures may be arranged in the X direction.

In the embodiments described above, the memory cell array 10 may have another configuration. For example, the memory pillar MP may have a structure in which three or more pillars are connected in the Z direction. In this case, a pillar penetrating the stacked wirings corresponding to word lines WL is added to the memory pillar MP. The memory pillar MP may include a plurality of joint portions JT. In connection with the above embodiments, reference was made to an example in which the memory pillar MP includes the joint portion JT. However, the joint portion JT does not have to be formed. In this case, in the memory pillar MP, a portion corresponding to memory hole LMH and a portion corresponding to memory hole UMH are directly connected.

In connection with the above embodiments, reference was made to an example in which the semiconductor memory device 1 is provided with such a circuit as the sense amplifier module 16 below the memory cell array 10, but this is not restrictive. For example, the semiconductor memory device 1 may have a configuration in which the memory cell array 10 and the sense amplifier module 16 are formed on the semiconductor substrate 20. In addition, the semiconductor memory device 1 may have a configuration in which a chip provided with the sense amplifier module 16 or the like and a chip provided with the memory cell array 10 are bonded together.

In connection with the above embodiments, reference was made to a configuration in which the word line WL and the select gate line SGS are adjacent to each other, and the word line WL and the select gate line SGD are adjacent to each other. However, this configuration is not restrictive. For example, a dummy word line may be provided between the uppermost one of the word line WL and the select gate line SGD. Likewise, a dummy word line may be provided between the lowermost one of the word line WL and the select gate line SGS. In addition, a conductive layer in the vicinity of the joint portion JT may be used as a dummy word line.

Although the drawings referred to in connection with the above embodiments show an example in which memory hole MH and slit SLT have a tapered shape, but this is not restrictive. For example, the memory hole MH may have a reverse taper shape, or may have a middle bulging shape. Similarly, the slit SLT may have a reverse taper shape, or may have middle bulging shape.

In connection with the above embodiments, reference was made to the case where the semiconductor layer 31 and the conductive layer 21 are electrically connected via the bottom of the memory pillar MP, but this case is not restrictive.. The semiconductor layer 31 and the conductive layer 21 may be electrically connected via the side surface of the memory pillar MP. In this case, those portions of the tunnel insulating film 32, insulating film 33 and block insulating film 34 which are formed on the side surface portion of the memory pillar MP are removed, and the semiconductor layer 31 and the conductive layer 21 are in contact with each other via the resultant region.

In the present specification, the term “connection” means that elements are electrically connected, and does not exclude the case where another element is interposed in between. In addition, “electrically connection” may use an insulator as long as the insulator does not affect the proper operation accomplished by the electrical connection. The expression “continuous” or “continuously provided” indicates that elements are formed in the same manufacturing process. In the portions that are continuously provided, no boundary is formed between the portions in a certain film or layer.

In the present specification, “substantially the same thickness” indicates that a layer (film) is formed by the same manufacturing process, and covers those variations which may be caused depending upon film formation positions. The “columnar” indicates that the structure is provided in a hole formed in the manufacturing process of the semiconductor memory device 1. The structures formed in memory holes LMH and UMH may be referred to as “pillars” respectively. That is, in the above embodiments, the memory pillar MP has a structure in which the pillar corresponding to memory hole UMH is formed on the pillar corresponding to memory hole LMH via the joint portion JT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked portion provided in a first region including a memory cell and in a second region different from the first region, the stacked portion including a plurality of first conductive layers, a plurality of second conductive layers and a first insulating layer, the first conductive layers being stacked in a first direction above a substrate, the first conductive layers being separated from each other, the second conductive layers being stacked in the first direction above the first conductive layers, the second conductive layers being separated from each other, and the first insulating layer being provided between an uppermost one of the first conductive layers and a lowermost one of the second conductive layers;
a pillar which penetrates the first conductive layers, the second conductive layers and the first insulating layer in the first region;
a plurality of first contacts respectively connected to the first conductive layers in the second region; and
a plurality of second contacts respectively connected to the second conductive layers in the second region,
wherein a thickness of the first insulating layer is greater in the first region than in the second region in the first direction.

2. The device of claim 1, wherein the stacked portion includes a portion which is located in a third region between the first region and the second region and in which an upper surface of the first insulating layer is inclined.

3. The device of claim 2, wherein the second conductive layers include inclined portions which are along the upper surface of the first insulating layer in the third region.

4. The device of claim 1, wherein the thickness of the first insulating layer in the second region is substantially equal to a thickness of a second insulating layer between adjacent ones of the first conductive layers in the first direction, and to a thickness of a third insulating layer between adjacent ones of the second conductive layers in the first direction.

5. The device of claim 1, wherein the pillar includes a first portion, a second portion and a joint portion, the first portion being provided to penetrate the first conductive layers, the second portion being provided to penetrate the second conductive layers, and the joint portion being provided between the first portion and the second portion, and
an outer diameter of the pillar in a cross section parallel to the substrate is larger at the joint portion than at an upper end of the first portion and is larger at the joint portion than at a lower end of the second portion.

6. The device of claim 1, wherein
in a region located between a region in which the first contacts are provided and a region in which the second contacts are provided within the second region, the stacked portion further includes a plurality of third conductive layers respectively provided in same layers as those of the second conductive layers, the third conductive layers being insulated from the second conductive layers.

7. The device of claim 1, wherein
in the second region, each of the first conductive layers includes a terrace portion that does not overlap an upper one of the first conductive layers, and each of the second conductive layers includes a terrace portion that does not overlap an upper one of the second conductive layers, the first contacts are connected to respective terrace portions of the first conductive layers, and the second contacts are connected to respective terrace portions of the second conductive layers.

8. The device of claim 1, wherein
in the second region, the first contacts and the second contacts are respectively formed in a plurality of holes which extend from an uppermost layer of the stacked portion and reach respective layers of the first conductive layers and the second conductive layers.

9. The device of claim 1, wherein the first insulating layer is disconnected in the second region.

10. The device of claim 9, wherein the stacked portion further includes, in the second region, an intermediate conductive layer which is located in a layer corresponding to the first insulating layer disconnected in the second region and which is other than the first conductive layers and the second conductive layers.

11. A semiconductor memory device comprising:
a stacked portion provided in a first region including a memory cell and in a second region different from the first region, the stacked portion including a plurality of first conductive layers, a plurality of second conductive layers, a first insulating layer and an intermediate conductive layer, the first conductive layers being stacked in a first direction above a substrate, the first conductive layers being separated from each other, the second conductive layers being stacked in the first direction above the first conductive layers, the second conductive layers being separated from each other, the first insulating layer being provided between an uppermost one of the first conductive layers and a lowermost one of the second conductive layers in the first region, and the intermediate conductive layer being provided between the uppermost one of the first conductive layers and the lowermost one of the second conductive layers in the second region such that the intermediate conductive layer is separated from the uppermost one of the first conductive layers and the lowermost one of the second conductive layers in the first direction;
a pillar which penetrates the first conductive layers, the second conductive layers and the first insulating layer in the first region;
a plurality of first contacts respectively connected to the first conductive layers in the second region; and
a plurality of second contacts respectively connected to the second conductive layers in the second region,
wherein the intermediate conductive layer is selectively provided in the second region out of the first region and the second region.

12. The device of claim 11, wherein a thickness of the first insulating layer in the first direction is greater than a thickness of the intermediate conductive layer in the first direction.

13. The device of claim 11, wherein the stacked portion includes a portion which is located in a third region between the first region and the second region and in which a side surface of the first insulating layer and a side surface of the intermediate conductive layer are in contact with each other.

14. The device of claim 11, wherein a thickness of the intermediate conductive layer in the first direction is substantially equal to a thickness of the first conductive layers in the first direction, and to a thickness of the second conductive layers in the first direction.

15. The device of claim 11, wherein
the pillar includes a first portion, a second portion and a joint portion, the first portion being provided to penetrate the first conductive layers, the second portion being provided to penetrate the second conductive layers, and the joint portion being provided between the first portion and the second portion, and
an outer diameter of the pillar in a cross section parallel to the substrate is larger at the joint portion than at an upper end of the first portion and is larger at the joint portion than at a lower end of the second portion.

16. The device of claim 11, wherein
in a region located between a region in which the first contacts are provided and a region in which the second contacts are provided within the second region, the stacked portion further includes a plurality of third conductive layers respectively provided in same layers as those of the second conductive layers, the third conductive layers being insulated from the second conductive layers.

17. The device of claim 11, wherein
in the second region, each of the first conductive layers includes a terrace portion that does not overlap an upper one of the first conductive layers, and each of the second conductive layers includes a terrace portion that does not overlap an upper one of the second conductive layers, the first contacts are connected to respective terrace portions of the first conductive layers, and the second contacts are connected to respective terrace portions of the second conductive layers.

18. The device of claim 11, wherein
in the second region, the first contacts and the second contacts are respectively formed in a plurality of holes which extend from an uppermost layer of the stacked portion and reach respective layers of the first conductive layers and the second conductive layers.

19. The device of claim 11, wherein a thickness of the first insulating layer in the first direction is greater than a thickness of a second insulating layer between adjacent ones of the first conductive layers in the first direction, and is greater than a thickness of a third insulating layer between adjacent ones of the second conductive layers in the first direction.

20. The device of claim 11, wherein a space between the uppermost one of the first conductive layers and the lowermost one of the second conductive layers in the first direction is substantially equal between in the first region and in the second region with each other.
